(19) United States
(12) Patent Application Publication
(10) Pub. No.: US 2026/0033273 A1
(43) Pub. Date: Jan. 29, 2026

(54) SUBSTRATE PROCESSING APPARATUS AND SUBSTRATE PROCESSING METHOD

(71) Applicant: SCREEN Holdings Co., Ltd., Kyoto (JP)

(72) Inventors: Kyosuke MURATA, Kyoto (JP); Daiki FUJII, Kyoto (JP); Tomohiro TAKAHASHI, Kyoto (JP)

(21) Appl. No.: 19/276,843

(22) Filed: Jul. 22, 2025

(30) Foreign Application Priority Data
Jul. 25, 2024 (JP) 2024-119563

(51) Int. Cl. H01L 21/67

(52) U.S. Cl. CPC H01L 21/67086

(57) ABSTRACT

A substrate processing apparatus includes: a processing tank storing an etching liquid; a substrate holder configured to immerse a substrate in the etching liquid; an etching liquid supply unit configured to supply the etching liquid into the processing tank, and including a first discharge hole in which a direction in which the etching liquid is discharged is directed to an upper portion of the substrate, and a second discharge hole disposed below the first discharge hole; an air bubble supply unit configured to supply air bubbles to the etching liquid from below the substrate; and a controller, wherein the controller controls the etching liquid supply unit to adjust a discharge amount of the etching liquid from the first discharge hole to be larger than a discharge amount of the etching liquid from the second discharge hole in a whole or part of a period of etching the substrate.

### BACKGROUND OF THE INVENTION

### (1) Field of the Invention

The present invention relates to a substrate processing apparatus and a substrate processing method. A substrate is, for example, any of a semiconductor wafer, a liquid crystal display substrate, an organic electroluminescence (EL) substrate, a flat panel display (FPD) substrate, an optical display substrate, a magnetic disk substrate, an optical disk substrate, a magneto-optical disk substrate, a photomask substrate, and a solar cell substrate.

### (2) Description of the Related Art

JP 2020-47885 A discloses a substrate processing apparatus. The substrate processing apparatus includes a processing tank, a substrate holder, an air bubble supply unit, and a plurality of processing liquid supply units. The plurality of processing liquid supply units are disposed to face side walls of the processing tank. The plurality of processing liquid supply units supply a processing liquid toward air bubbles supplied from the air bubble supply unit. The plurality of processing liquid supply units each belong to at least one of a plurality of groups. The plurality of processing liquid supply units supply the processing liquid toward the air bubbles in a different period for each group. As a result, the substrate processing apparatus according to JP 2020-47885 A allows passage of the air bubbles along the entire surface of a substrate, thereby reducing a region with insufficient air bubbles.

However, the substrate processing apparatus according to JP 2020-47885 A has room for improving processing unevenness in the surface of the substrate.

The present invention has been made in view of such circumstances, and an object thereof is to provide a substrate processing apparatus and a substrate processing method capable of reducing processing unevenness in a substrate surface.

### SUMMARY OF THE INVENTION

As a result of intensive studies to solve the above problems, the inventors have found that an etching amount in an upper portion of a substrate is reduced. The inventors have found, for example, the following as one of the causes. That is, air bubbles supplied from an air bubble supply unit gather around an upper portion of a processing tank, resulting in a decrease in temperature of an etching liquid around the upper portion of the processing tank. This decrease in temperature of the etching liquid around the upper portion of the processing tank leads to a decrease in etching rate in the upper portion of the substrate. The inventors have found that it is difficult to increase the etching rate in the upper portion of the substrate even if air bubbles are supplied in a conventional etching liquid supply method.

The present invention has the following configuration on the basis of such findings. That is, the present invention is a substrate processing apparatus for processing a substrate, including: a processing tank configured to store an etching liquid for etching the substrate; a substrate holder configured to hold the substrate and immerse the substrate in the etching liquid stored in the processing tank; an etching liquid supply unit disposed in the processing tank and configured to supply the etching liquid into the processing tank, the etching liquid supply unit including at least a first discharge hole in which a direction in which the etching liquid is discharged is directed to an upper portion of the substrate, and a second discharge hole disposed below the first discharge hole and configured to discharge the etching liquid; an air bubble supply unit disposed in the processing tank and configured to supply a plurality of air bubbles to the etching liquid from below the substrate; and a controller configured to control processing on the substrate, wherein the controller controls the etching liquid supply unit to adjust a discharge amount of the etching liquid so that a discharge amount of the etching liquid discharged from the first discharge hole is larger than a discharge amount of the etching liquid discharged from the second discharge hole in a whole or part of a period in which the substrate is etched.

The substrate processing apparatus processes the substrate. The substrate processing apparatus includes the processing tank, the substrate holder, the etching liquid supply unit, the air bubble supply unit, and the controller. The processing tank stores the etching liquid for etching the substrate. The substrate holder holds the substrate and immerses the substrate in the etching liquid stored in the processing tank. The etching liquid supply unit is disposed in the processing tank and supplies the etching liquid into the processing tank. The etching liquid supply unit includes at least the first discharge hole in which the direction in which the etching liquid is discharged is directed to the upper portion of the substrate, and the second discharge hole that is disposed below the first discharge hole and discharges the etching liquid. The air bubble supply unit is disposed in the processing tank and supplies the plurality of air bubbles to the etching liquid from below the substrate. Here, the air bubbles supplied from the air bubble supply unit gather around the upper portion of the processing tank, possibly resulting in a decrease in temperature of the etching liquid around the upper portion of the processing tank. This decrease in temperature of the etching liquid around the upper portion of the processing tank may lead to a decrease in etching rate in the upper portion of the substrate.

Therefore, the present invention is further configured as follows. The controller controls processing on the substrate. The controller controls the etching liquid supply unit to adjust the discharge amount of the etching liquid so that the discharge amount of the etching liquid discharged from the first discharge hole is larger than the discharge amount of the etching liquid discharged from the second discharge hole in the whole or a part of the period in which the substrate is etched. As a result, even if a situation occurs in which the air bubbles are likely to gather around the upper portion of the processing tank, the etching liquid is reliably easily supplied to the upper portion of the substrate. Therefore, the etching liquid easily etches the upper portion of the substrate. That is, the etching rate in the upper portion of the substrate increases. As a result, the uniformity of etching in the surface of the substrate is improved. In this manner, the present invention can reduce processing unevenness in the surface of the substrate.

In the substrate processing apparatus according to the present invention, it is preferable that the processing tank includes a bottom portion and a side wall portion that extends upward from the bottom portion, the side wall portion includes a first side wall portion and a second side wall portion that faces the first side wall portion, and the first discharge hole and the second discharge hole are provided on each of the first side wall portion side and the second side wall portion side. That is, the etching liquid is supplied from the opposite sides of the first side wall portion side and the second side wall portion side toward the upper portion of the substrate. Therefore, the etching liquid is more easily supplied to the upper portion of the substrate.

In one example, an etching liquid supply pipe having the first discharge hole and an etching liquid supply pipe having the second discharge hole are provided on each of the first side wall portion and the second side wall portion. In another example, the first discharge hole and the second discharge hole are directly provided in each of the first side wall portion and the second side wall portion. In yet another example, the etching liquid supply pipe having the first discharge hole and the etching liquid supply pipe having the second discharge hole are provided slightly away from each of the first side wall portion and the second side wall portion.

In the substrate processing apparatus according to the present invention, it is preferable that the etching liquid supply unit includes a third discharge hole disposed in the bottom portion, and discharges the etching liquid from the third discharge hole to a lower side of the substrate, and the controller controls the etching liquid supply unit to adjust the discharge of the etching liquid so that the discharge amount of the etching liquid discharged from the first discharge hole is larger than at least one of the discharge amount of the etching liquid discharged from the second discharge hole or a discharge amount of the etching liquid discharged from the third discharge hole in the whole or a part of the period in which the substrate is etched. Therefore, the etching liquid is more easily supplied to the upper portion of the substrate.

In one example, an etching liquid supply pipe having the third discharge hole is provided on the bottom portion. In another example, the third discharge hole is directly provided in the bottom portion. In yet another example, the etching liquid supply pipe having the third discharge hole is provided slightly away from the bottom portion.

In the substrate processing apparatus according to the present invention, it is preferable that the controller controls the etching liquid supply unit to adjust the discharge amount of the etching liquid so that a period in which the etching liquid is discharged from the first discharge hole is longer than a period in which the etching liquid is discharged from the second discharge hole. Therefore, it is easy to make the discharge amount of the etching liquid discharged from the first discharge hole larger than the discharge amount of the etching liquid discharged from the second discharge hole.

In the substrate processing apparatus according to the present invention, it is preferable that the controller controls the etching liquid supply unit to adjust the discharge amount of the etching liquid so that an amount per unit time of the etching liquid discharged from the first discharge hole is larger than an amount per unit time of the etching liquid discharged from the second discharge hole. Therefore, it is easy to make the discharge amount of the etching liquid discharged from the first discharge hole larger than the discharge amount of the etching liquid discharged from the second discharge hole.

The present invention is a substrate processing apparatus for processing a substrate, including: a processing tank configured to store an etching liquid for etching the substrate; a substrate holder configured to hold the substrate and immerse the substrate in the etching liquid stored in the processing tank; an etching liquid supply unit disposed in the processing tank and configured to supply the etching liquid into the processing tank, the etching liquid supply unit including at least a first discharge hole in which a direction in which the etching liquid is discharged is directed to an upper portion of the substrate, and a second discharge hole disposed below the first discharge hole and configured to discharge the etching liquid; an air bubble supply unit disposed in the processing tank and configured to supply a plurality of air bubbles to the etching liquid from below the substrate; and a controller configured to control processing on the substrate, wherein the controller controls the etching liquid supply unit to switch between discharge of the etching liquid from the first discharge hole and discharge of the etching liquid from the second discharge hole, and controls the air bubble supply unit to adjust a discharge amount of the plurality of air bubbles so that a discharge amount of the plurality of air bubbles during a period in which the etching liquid is discharged from the first discharge hole is smaller than a discharge amount of the plurality of air bubbles during a period in which the etching liquid is discharged from the second discharge hole. As a result, during the period in which the etching liquid is discharged from the first discharge hole, the etching liquid directed toward the upper portion of the substrate is less likely to be dispersed by the air bubbles. That is, the etching liquid is intensively supplied to the upper portion of the substrate. Therefore, the etching rate in the upper portion of the substrate can be increased. As a result, the uniformity of etching in the surface of the substrate is improved. In this manner, the present invention can reduce processing unevenness in the surface of the substrate.

In the substrate processing apparatus according to the present invention, it is preferable that the controller controls the air bubble supply unit to stop discharge of the plurality of air bubbles during the period in which the etching liquid is discharged from the first discharge hole. As a result, during a period in which the discharge of the plurality of air bubbles is stopped, the etching liquid directed toward the upper portion of the substrate is further less likely to be dispersed by the air bubbles. That is, the etching liquid is more easily intensively supplied to the upper portion of the substrate. Therefore, the etching rate in the upper portion of the substrate can be further increased. As a result, the uniformity of etching in the surface of the substrate can be further improved.

In the substrate processing apparatus according to the present invention, it is preferable that the controller controls the air bubble supply unit to switch between discharge of the plurality of air bubbles and discharge stop of the plurality of air bubbles during the period in which the etching liquid is discharged from the first discharge hole. It is possible to increase the etching rate in the upper portion of the substrate while maintaining the effect of supplying the plurality of air bubbles to the substrate.

The present invention is a substrate processing method for processing a substrate, including: immersing a substrate held by a substrate holder in an etching liquid stored in a processing tank; supplying the etching liquid into the processing tank in which the substrate is immersed; and supplying a plurality of air bubbles into the processing tank in which the substrate is immersed, wherein the supplying of the etching liquid includes adjusting a discharge amount of the etching liquid so that a discharge amount of the etching liquid discharged toward an upper portion of the substrate is larger than a discharge amount of the etching liquid discharged toward a lower portion of the substrate in a whole or part of a period in which the substrate is etched.

The substrate processing method is a method of processing the substrate. The substrate processing method includes immersing the substrate held by the substrate holder in the etching liquid stored in the processing tank. The substrate processing method includes supplying the etching liquid into the processing tank in which the substrate is immersed. The substrate processing method includes supplying the plurality of air bubbles into the processing tank in which the substrate is immersed. When the air bubbles are discharged, a situation occurs in which the air bubbles are likely to gather around the upper portion of the processing tank. Supplying the etching liquid into the processing tank in which the substrate is immersed includes adjusting the discharge amount of the etching liquid so that the discharge amount of the etching liquid discharged toward the upper portion of the substrate is larger than the discharge amount of the etching liquid discharged toward the lower portion of the substrate in the whole or a part of the period in which the substrate is etched. As a result, even if a situation occurs in which the air bubbles are likely to gather around the upper portion of the processing tank, the etching liquid is reliably easily supplied to the upper portion of the substrate. Therefore, the etching liquid easily etches the upper portion of the substrate. That is, the etching rate in the upper portion of the substrate increases. As a result, the uniformity of etching in the surface of the substrate is improved. In this manner, the present invention can reduce processing unevenness in the surface of the substrate.

The present invention is a substrate processing method for processing a substrate, including: immersing a substrate held by a substrate holder in an etching liquid stored in a processing tank; supplying the etching liquid into the processing tank in which the substrate is immersed; and supplying a plurality of air bubbles into the processing tank in which the substrate is immersed, wherein the supplying of the etching liquid into the processing tank in which the substrate is immersed includes switching between discharging the etching liquid toward an upper portion of the substrate and discharging the etching liquid toward a lower portion of the substrate during a period in which the substrate is etched, and the supplying of the plurality of air bubbles into the processing tank in which the substrate is immersed includes adjusting a discharge amount of the plurality of air bubbles so that a discharge amount of the plurality of air bubbles during a period in which the etching liquid is discharged toward the upper portion of the substrate is smaller than a discharge amount of the plurality of air bubbles during a period in which the etching liquid is discharged toward the lower portion of the substrate.

The substrate processing method is a method of processing the substrate. The substrate processing method includes immersing the substrate held by the substrate holder in the etching liquid stored in the processing tank. The substrate processing method includes supplying the etching liquid into the processing tank in which the substrate is immersed. The substrate processing method includes supplying the plurality of air bubbles into the processing tank in which the substrate is immersed. The supplying of the etching liquid into the processing tank in which the substrate is immersed includes switching between discharging the etching liquid toward the upper portion of the substrate and discharging the etching liquid toward the lower portion of the substrate during the period in which the substrate is etched. The supplying of the plurality of air bubbles into the processing tank in which the substrate is immersed includes adjusting the discharge amount of the plurality of air bubbles so that the discharge amount of the plurality of air bubbles during the period in which the etching liquid is discharged toward the upper portion of the substrate is smaller than the discharge amount of the plurality of air bubbles during the period in which the etching liquid is discharged toward the lower portion of the substrate. As a result, during the period in which the etching liquid is discharged toward the upper portion of the substrate, the etching liquid directed toward the upper portion of the substrate is less likely to be dispersed by the air bubbles. That is, the etching liquid is intensively supplied to the upper portion of the substrate. Therefore, the etching rate in the upper portion of the substrate can be increased. As a result, the uniformity of etching in the surface of the substrate is improved. In this manner, the present invention can reduce processing unevenness in the surface of the substrate.

The present invention also discloses the following invention.

A substrate processing apparatus for processing a substrate, including: a processing tank configured to store an etching liquid for etching the substrate; a substrate holder configured to hold the substrate and immerse the substrate in the etching liquid stored in the processing tank; an etching liquid supply unit disposed in the processing tank and configured to supply the etching liquid into the processing tank, the etching liquid supply unit including at least a first discharge hole in which a direction in which the etching liquid is discharged is directed to an upper portion of the substrate, and a second discharge hole disposed below the first discharge hole and configured to discharge the etching liquid; an etching liquid discharge amount adjustment unit configured to adjust a discharge amount of the etching liquid; an air bubble supply unit disposed in the processing tank and configured to supply a plurality of air bubbles to the etching liquid from below the substrate; and a controller configured to control processing on the substrate, wherein the controller controls the etching liquid discharge amount adjustment unit to adjust, in a plurality of stages, a minute discharge amount discharged slightly when the etching liquid is adjusted not to be discharged from at least one of the first discharge hole or the second discharge hole in a whole or part of a period in which the substrate is etched.

The substrate processing apparatus includes the etching liquid discharge amount adjustment unit that adjusts the discharge amount of the etching liquid. The controller controls the etching liquid discharge amount adjustment unit to adjust, in a plurality of stages, the minute discharge amount discharged slightly when the etching liquid is adjusted not to be discharged from at least one of the first discharge hole or the second discharge hole in the whole or a part of the period in which the substrate is etched. This makes it possible for the etching liquid discharge amount adjustment unit not only to adjust whether the etching liquid is discharged or not from at least one of the first discharge hole or the second discharge hole, but also to adjust the discharge amount at the time of slightly discharging the etching liquid. Therefore, the etching rate in the surface of the substrate can be finely adjusted. As a result, the uniformity of etching in the surface of the substrate can be finely adjusted.

### BRIEF DESCRIPTION OF THE DRAWINGS

For the purpose of illustrating the invention, there are shown in the drawings several forms which are presently preferred, it being understood, however, that the invention is not limited to the precise arrangement and instrumentalities shown.

FIG. 1 is a schematic cross-sectional view illustrating a substrate processing apparatus according to a first embodiment of the present invention;

FIG. 2 is a schematic plan view illustrating an etching liquid supply unit and an air bubble supply unit according to the first embodiment;

FIG. 3 is a drawing illustrating an example of a processing procedure of the etching liquid supply unit and the air bubble supply unit according to the first embodiment;

FIGS. 4A to 4C are drawings illustrating states in a processing tank in which supply of an etching liquid and air bubbles is controlled according to procedure steps S1 to S3 of the first embodiment;

FIGS. 5A to 5C are drawings illustrating states in the processing tank in which the supply of the etching liquid and the air bubbles is controlled according to procedure step S4;

FIGS. 6A and 6B are map images illustrating the uniformity of etching in a substrate surface in a case where the supply of the etching liquid and the air bubbles is controlled according to procedure steps S1 and S2;

FIGS. 7A and 7B are map images illustrating the uniformity of etching in the substrate surface in a case where the supply of the etching liquid and the air bubbles is controlled according to procedure steps S3 and S4;

FIG. 8 is a flowchart illustrating a substrate processing method according to the first embodiment;

FIG. 9 is a drawing illustrating an example of a processing procedure of an etching liquid supply unit and an air bubble supply unit according to a second embodiment;

FIGS. 10A to 10C are drawings illustrating states in a processing tank in which supply of an etching liquid and air bubbles is controlled according to procedure steps S1 to S3 of the second embodiment;

FIG. 11 is a flowchart illustrating a substrate processing method according to the second embodiment;

FIG. 12 is a drawing illustrating an example of a processing procedure of an etching liquid supply unit and an air bubble supply unit according to an eighth modification;

FIGS. 13A and 13B are map images illustrating the uniformity of etching in a substrate surface in a case where supply of an etching liquid and air bubbles is controlled according to procedure step S3 of the first embodiment and the eighth modification;

FIG. 14 is a drawing illustrating an example of a processing procedure of an etching liquid supply unit and an air bubble supply unit according to a ninth modification;

FIG. 15 is a drawing illustrating an example of a processing procedure of an etching liquid supply unit and an air bubble supply unit according to an eleventh modification;

FIG. 16 is a drawing illustrating an example of a processing procedure of an etching liquid supply unit and an air bubble supply unit according to a thirteenth modification;

FIG. 17 is a drawing illustrating an example of a processing procedure of an etching liquid supply unit and an air bubble supply unit according to a sixteenth modification; and

FIGS. 18A and 18B are map images illustrating the uniformity of etching in a substrate surface in a case where supply of an etching liquid and air bubbles is controlled according to procedure steps S3 and S4 of the sixteenth modification.

### DESCRIPTION OF THE PREFERRED EMBODIMENTS

Hereinafter, embodiments of the present invention will be described with reference to the drawings.

### 1. First Embodiment

### 1-1. Outline of Substrate Processing Apparatus

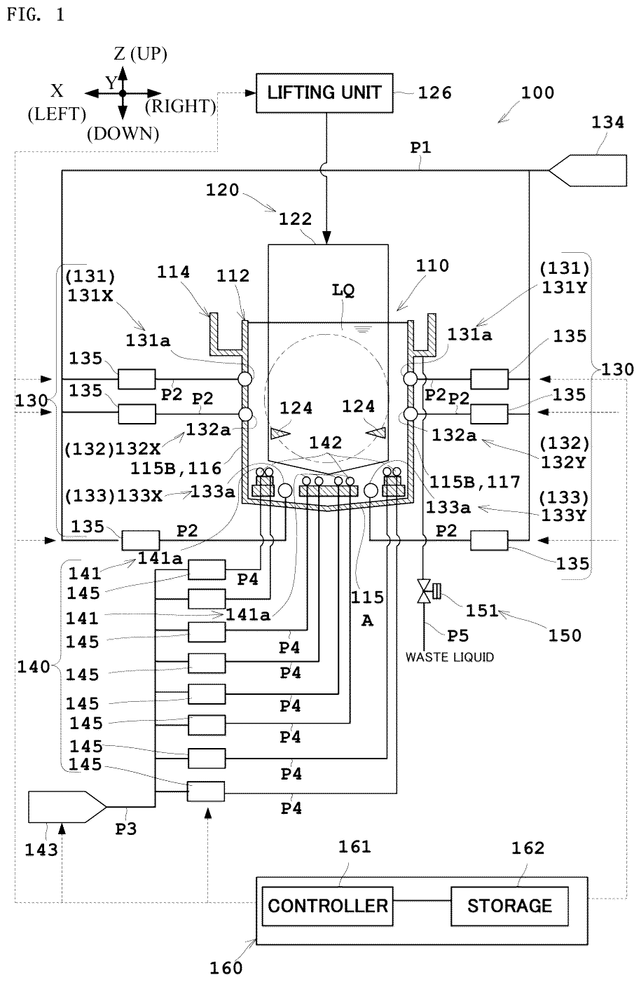

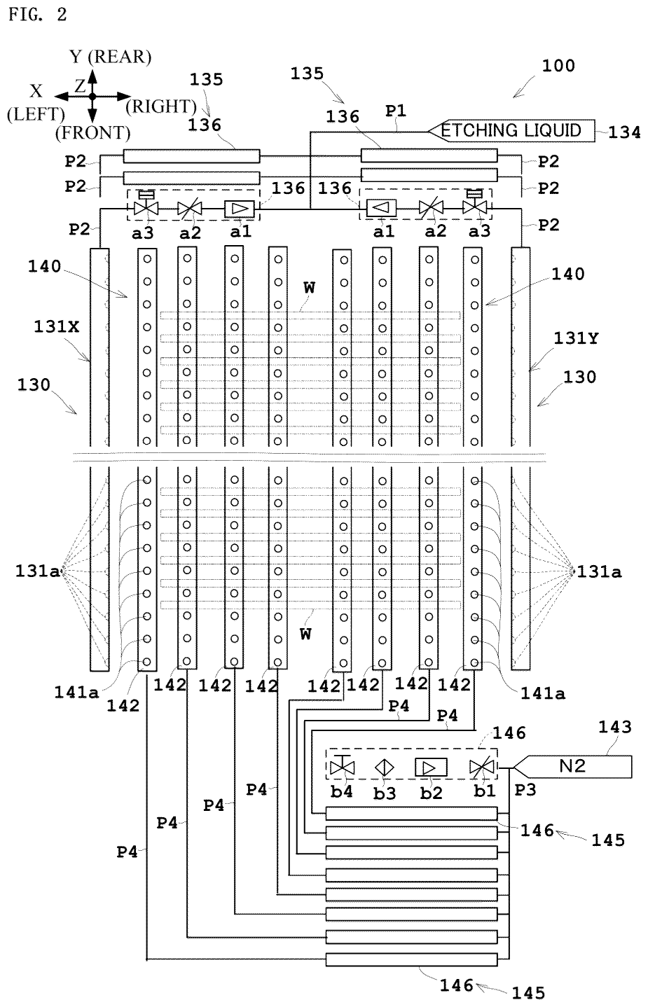

A substrate processing apparatus 100 according to a first embodiment of the present invention will be described with reference to FIGS. 1 to 8. First, the substrate processing apparatus 100 will be described with reference to FIGS. 1 and 2.

FIG. 1 is a schematic cross-sectional view illustrating the substrate processing apparatus 100. FIG. 2 is a schematic plan view illustrating an etching liquid supply unit 130 and an air bubble supply unit 140.

In the present specification, for convenience, a direction in which a first side wall 116 and a second side wall 117 constituting a processing tank 110 are arranged is referred to as “width direction X”. Of the width direction X, a direction from the second side wall 117 toward the first side wall 116 is referred to as “left side”. A direction opposite to the left side is referred to as “right side”. A direction orthogonal to the width direction X, that is, a direction in which substrates W are arranged in the processing tank 110 is referred to as “front-rear direction Y”. One direction in the “front-rear direction Y” is referred to as “front side” as appropriate. A direction opposite to the front side is referred to as “rear side”. A depth direction of the processing tank 110 is referred to as “vertical direction Z”. A direction from a bottom portion 115A of the processing tank 110 toward the surface of an etching liquid LQ is referred to as “upper side”. A direction opposite to the upper side is referred to as “lower side”. In each drawing, front, rear, right, left, up, and down are appropriately shown for reference.

The substrate processing apparatus 100 illustrated in FIG. 1 processes a substrate W. The substrate processing apparatus 100 is of batch type, and collectively processes a plurality of substrates W with the etching liquid LQ. Specifically, the substrate processing apparatus 100 collectively processes the plurality of substrates W constituting a lot. One lot is, for example, 25 sheets or 50 sheets. The substrate processing apparatus 100 can also process one substrate W.

In the first embodiment, the substrate W is a semiconductor wafer. The substrate W may be, for example, any of a liquid crystal display substrate, an organic electroluminescence (EL) substrate, a flat panel display (FPD) substrate, an optical display substrate, a magnetic disk substrate, an optical disk substrate, a magneto-optical disk substrate, a photomask substrate, and a solar cell substrate.

The substrate processing apparatus 100 includes the processing tank 110, a substrate holder 120, the etching liquid supply unit 130, the air bubble supply unit 140, and a drainage unit 150. The substrate processing apparatus 100 further includes a common pipe P1, a plurality of supply pipes P2, a common pipe P3, a plurality of supply pipes P4, and a drainage pipe P5.

The processing tank 110 stores the etching liquid LQ for etching the substrate W. Specifically, the processing tank 110 immerses the plurality of substrates W in the etching liquid LQ to etch the plurality of substrates W.

The etching liquid LQ is, for example, phosphoric acid (H3PO4). The etching liquid may be, for example, dilute hydrofluoric acid (DHF), hydrofluoric acid (HF), nitric hydrofluoric acid (a mixed solution of hydrofluoric acid and nitric acid (HNO3)), buffered hydrofluoric acid (BHF), ammonium fluoride, HFEG (a mixed solution of hydrofluoric acid and ethylene glycol), sulfuric acid, acetic acid, nitric acid, hydrochloric acid, ammonia water, hydrogen peroxide water, organic acids (for example, citric acid, oxalic acid), organic alkalis (for example, TMAH: tetramethylammonium hydroxide), a sulfuric acid-hydrogen peroxide mixture (SPM), an ammonia-hydrogen peroxide mixture (SC1), a hydrochloric acid-hydrogen peroxide mixture (SC2), isopropyl alcohol (IPA), a surfactant, a corrosion inhibitor, or a hydrophobic agent.

The processing tank 110 has a double tank structure including an inner tank 112 and an outer tank 114. Each of the inner tank 112 and the outer tank 114 has an upper opening that opens upward. The inner tank 112 stores the etching liquid LQ and is configured to be able to accommodate the plurality of substrates W. The outer tank 114 is provided on an outer surface of the upper opening of the inner tank 112. An upper edge of the outer tank 114 is higher than an upper edge of the inner tank 112. The etching liquid LQ overflowing the upper edge of the inner tank 112 is collected by the outer tank 114.

The processing tank 110 includes the bottom portion 115A and a side wall portion 115B that extends upward from the bottom portion 115A. The side wall portion 115B includes the first side wall 116 and the second side wall 117 that face each other in the width direction X. Specifically, the inner tank 112 includes the first side wall 116 and the second side wall 117.

The side wall portion 115B corresponds to an example of a “side wall portion” of the present invention. The first side wall 116 corresponds to an example of a “first side wall portion” of the present invention. The second side wall 117 corresponds to an example of a “second side wall portion” of the present invention.

The substrate holder 120 holds the plurality of substrates W. The substrate holder 120 can also hold one substrate W. The substrate holder 120 immerses the plurality of substrates W arranged at intervals in the front-rear direction Y in the etching liquid LQ stored in the processing tank 110.

Specifically, the substrate holder 120 moves upward or downward along the vertical direction Z while holding the plurality of substrates W. When the substrate holder 120 moves downward, the plurality of substrates W held by the substrate holder 120 are immersed in the etching liquid LQ stored in the inner tank 112. When the substrate holder 120 moves upward, the plurality of substrates W held by the substrate holder 120 are pulled up from the etching liquid LQ stored in the inner tank 112.

The substrate holder 120 includes a body plate 122 and holding rods 124. The body plate 122 is a plate extending in the vertical direction Z. The holding rods 124 extend to the front side from the body plate 122. The plurality of holding rods 124 are in contact with lower edges of the plurality of substrates W to hold the substrates W in a standing position (vertical position) in a state where the substrates W are arranged at intervals along the front-rear direction Y.

The substrate holder 120 may further include a lifting unit 126. The lifting unit 126 moves up and down the body plate 122 between a processing position where the plurality of substrates W held by the substrate holder 120 are placed in the inner tank 112 and a retracted position where the plurality of substrates W held by the substrate holder 120 are placed above the inner tank 112. Therefore, when the body plate 122 is moved to the processing position by the lifting unit 126, the plurality of substrates W held by the holding rods 124 are immersed in the etching liquid LQ. As a result, processing is performed on the plurality of substrates W.

### 1-2. Etching Liquid Supply Unit and Air Bubble Supply Unit

As illustrated in FIG. 1, the etching liquid supply unit 130 is disposed in the processing tank 110.

The etching liquid supply unit 130 includes, for example, an upper etching liquid supply unit 131, a lower etching liquid supply unit 132, and a bottom etching liquid supply unit 133. The upper etching liquid supply unit 131 is located in an upper layer of the processing tank 110. The lower etching liquid supply unit 132 is located below the upper etching liquid supply unit 131, for example, in a middle layer or a lower layer of the processing tank 110. The bottom etching liquid supply unit 133 is located below the lower etching liquid supply unit 132, for example, in a bottom layer of the processing tank 110.

The etching liquid supply unit 130, the upper etching liquid supply unit 131, the lower etching liquid supply unit 132, and the bottom etching liquid supply unit 133 correspond to an example of an “etching liquid supply unit” of the present invention.

Each of the upper etching liquid supply unit 131, the lower etching liquid supply unit 132, and the bottom etching liquid supply unit 133 includes an etching liquid discharge amount adjustment unit 135.

The air bubble supply unit 140 is provided at a plurality of locations of the bottom portion 115A of the processing tank 110. The air bubble supply unit 140 includes an air bubble discharge amount adjustment unit 145.

The etching liquid supply unit 130 supplies the etching liquid LQ into the processing tank 110. The etching liquid supply unit 130 can supply the etching liquid LQ into the processing tank 110 in a state where the processing tank 110 stores the etching liquid LQ and the substrate W is immersed therein.

The etching liquid supply unit 130 extends along the front-rear direction Y. The etching liquid supply unit 130 is, for example, an etching liquid supply pipe. A material of the etching liquid supply pipe is, for example, quartz or polyvinyl chloride (PVC). The etching liquid supply pipe is disposed on each of the first side wall 116 and the second side wall 117.

The upper etching liquid supply unit 131 is disposed above the lower etching liquid supply unit 132. The lower etching liquid supply unit 132 is disposed below the upper etching liquid supply unit 131. That is, an upper etching liquid supply pipe corresponding to the upper etching liquid supply unit 131 and a lower etching liquid supply pipe corresponding to the lower etching liquid supply unit 132 are disposed side by side in the vertical direction z on each of the first side wall 116 and the second side wall 117.

The upper etching liquid supply unit 131 includes an upper discharge hole 131a. The upper discharge hole 131a is formed in the upper etching liquid supply pipe. That is, the upper discharge hole 131a is disposed on each of the first side wall 116 side and the second side wall 117 side in the upper etching liquid supply pipe.

The upper discharge hole 131a corresponds to an example of a “first discharge hole” of the present invention.

The upper discharge hole 131a discharges the etching liquid LQ. In the upper discharge hole 131a, a direction in which the etching liquid LQ is discharged is directed to an upper portion of the substrate W. The upper portion of the substrate W is, for example, above the center of the substrate W held by the substrate holder 120 (upper half). The upper portion of the substrate W may be, for example, above the center of the upper half of the substrate W. The upper discharge hole 131a is configured to easily supply the etching liquid LQ to the upper portion of the substrate W.

The lower etching liquid supply unit 132 includes a lower discharge hole 132a. The lower discharge hole 132a discharges the etching liquid LQ. The lower discharge hole 132a is disposed below the upper discharge hole 131a. The lower discharge hole 132a is formed in the lower etching liquid supply pipe. That is, the lower discharge hole 132a is disposed on each of the first side wall 116 side and the second side wall 117 side in the lower etching liquid supply pipe.

The lower discharge hole 132a corresponds to an example of a “second discharge hole” of the present invention.

The bottom etching liquid supply unit 133 includes a bottom discharge hole 133a. The bottom discharge hole 133a is disposed below the lower discharge hole 132a. The bottom discharge hole 133a is formed in a bottom etching liquid supply pipe. The bottom discharge hole 133a is disposed on the bottom portion 115A side in the bottom etching liquid supply pipe. The bottom etching liquid supply unit 133 discharges the etching liquid LQ from the bottom discharge hole 133a to the lower side of the substrate W.

The bottom discharge hole 133a corresponds to an example of a “third discharge hole” of the present invention.

The upper discharge hole 131a is directed obliquely upward. The upper portion of the substrate W is positioned obliquely above the upper discharge hole 131a. The lower discharge hole 132a is directed slightly obliquely upward. An intermediate portion of the substrate W is positioned slightly obliquely above the lower discharge hole 132a. The bottom discharge hole 133a is directed largely obliquely upward. A lower portion of the substrate W is positioned close to a region immediately above the bottom discharge hole 133a. As described above, the upper discharge hole 131a, the lower discharge hole 132a, and the bottom discharge hole 133a are configured to be able to discharge the etching liquid LQ toward the upper portion, the intermediate portion, and the lower portion of the substrate W.

The upper etching liquid supply unit 131 includes an upper etching liquid supply unit 131X disposed on the first side wall 116 and an upper etching liquid supply unit 131Y disposed on the second side wall 117. The upper discharge hole 131a is formed in each of the upper etching liquid supply units 131X and 131Y.

The lower etching liquid supply unit 132 includes a lower etching liquid supply unit 132X disposed on the first side wall 116 and a lower etching liquid supply unit 132Y disposed on the second side wall 117. The lower discharge hole 132a is formed in each of the lower etching liquid supply units 132X and 132Y.

The bottom etching liquid supply unit 133 includes a bottom etching liquid supply unit 133X disposed closer to the first side wall 116 on the bottom portion 115A and a bottom etching liquid supply unit 133Y disposed closer to the second side wall 117 on the bottom portion 115A. The bottom discharge hole 133a is formed in each of the bottom etching liquid supply units 133X and 133Y.

The etching liquid discharge amount adjustment unit 135 adjusts the discharge amount of the etching liquid LQ discharged from the etching liquid supply unit 130 for each unit of the etching liquid supply unit 130. In other words, the etching liquid discharge amount adjustment unit 135 adjusts the discharge amount of the etching liquid LQ discharged into the processing tank 110 by the etching liquid supply unit 130 for each unit of the etching liquid supply unit 130.

The adjustment of the discharge amount of the etching liquid LQ includes making the discharge amount of the etching liquid LQ constant, increasing the discharge amount of the etching liquid LQ, decreasing the discharge amount of the etching liquid LQ, and making the discharge amount of the etching liquid LQ zero. In the first embodiment, the etching liquid discharge amount adjustment unit 135 switches each unit of the etching liquid supply unit 130 between supply and supply stop of the etching liquid LQ from the etching liquid supply unit 130 into the processing tank 110. In other words, the etching liquid discharge amount adjustment unit 135 switches each unit of the etching liquid supply unit 130 between the supply and supply stop of the etching liquid LQ from an etching liquid supply source 134 to the upper etching liquid supply unit 131, the lower etching liquid supply unit 132, and the bottom etching liquid supply unit 133.

Specifically, the etching liquid discharge amount adjustment unit 135 is provided in each of the upper etching liquid supply unit 131, the lower etching liquid supply unit 132, and the bottom etching liquid supply unit 133. The plurality of supply pipes P2 are individually provided in the upper etching liquid supply unit 131, the lower etching liquid supply unit 132, and the bottom etching liquid supply unit 133. One ends of the supply pipes P2 are individually connected to the upper etching liquid supply unit 131, the lower etching liquid supply unit 132, and the bottom etching liquid supply unit 133. The other ends of the supply pipes P2 are connected to the common pipe P1. The common pipe P1 is connected to the etching liquid supply source 134.

As illustrated in FIG. 2, the etching liquid discharge amount adjustment unit 135 includes an etching liquid flow rate adjustment mechanism 136. The etching liquid flow rate adjustment mechanism 136 is disposed in each of the supply pipes P2. The etching liquid flow rate adjustment mechanism 136 supplies the etching liquid LQ supplied from the etching liquid supply source 134 and the common pipe P1 to the corresponding unit of the etching liquid supply unit 130 through the corresponding supply pipe P2. The etching liquid flow rate adjustment mechanism 136 also adjusts the discharge amount of the etching liquid LQ discharged from each of the upper etching liquid supply unit 131, the lower etching liquid supply unit 132, and the bottom etching liquid supply unit 133. In other words, the etching liquid flow rate adjustment mechanism 136 adjusts the discharge amount of the etching liquid LQ discharged into the processing tank 110 by each of the upper etching liquid supply unit 131, the lower etching liquid supply unit 132, and the bottom etching liquid supply unit 133. In the first embodiment, the etching liquid flow rate adjustment mechanism 136 switches between the supply and supply stop of the etching liquid LQ from each of the upper etching liquid supply unit 131, the lower etching liquid supply unit 132, and the bottom etching liquid supply unit 133 to the processing tank 110. In other words, in the first embodiment, the etching liquid flow rate adjustment mechanism 136 switches between the supply and supply stop of the etching liquid LQ from the etching liquid supply source 134 to each of the upper etching liquid supply unit 131, the lower etching liquid supply unit 132, and the bottom etching liquid supply unit 133.

Specifically, as illustrated in FIG. 2, the etching liquid flow rate adjustment mechanism 136 includes a flow meter a1, an adjustment valve a2, and a valve a3. The flow meter a1, the adjustment valve a2, and the valve a3 are disposed in the supply pipe P2 in this order from the upstream to the downstream of the supply pipe P2.

The flow meter a1 measures the flow rate of the etching liquid LQ flowing through the supply pipe P2. The adjustment valve a2 adjusts the opening degree of the supply pipe P2 to adjust the flow rate of the etching liquid LQ flowing through the supply pipe P2, and adjust the discharge amount of the etching liquid LQ supplied from the etching liquid supply unit 130 into the processing tank 110. The adjustment valve a2 also adjusts the discharge amount of the etching liquid LQ on the basis of a measurement result of the flow meter a1. For example, a mass flow controller may be provided instead of the flow meter a1 and the adjustment valve a2. The valve a3 opens and closes the supply pipe P2. That is, the valve a3 switches between the supply and supply stop of the etching liquid LQ from the etching liquid supply unit 130 into the processing tank 110. The etching liquid flow rate adjustment mechanism 136 may include a filter that removes foreign substances in the etching liquid LQ.

Returning to FIG. 1, the drainage unit 150 drains the etching liquid LQ collected in the outer tank 114 through the drainage pipe P5. Specifically, a drainage pipe 151 is connected to the outer tank 114. The drainage pipe 151 is disposed in the drainage pipe P5. The drainage unit 150 includes, for example, a valve, and closes or opens a flow path of the drainage pipe P5.

The air bubble supply unit 140 is disposed inside the processing tank 110. The air bubble supply unit 140 supplies a gas (inert gas) supplied from the air bubble discharge amount adjustment unit 145 into the etching liquid LQ of the processing tank 110. Specifically, the air bubble supply unit 140 supplies air bubbles BB of an inert gas into the etching liquid LQ of the processing tank 110. The inert gas is, for example, a nitrogen gas (N2). The inert gas may be an argon gas (Ar).

As illustrated in FIG. 2, the air bubble supply unit 140 includes at least one air bubble supply pipe 142. In the first embodiment, the air bubble supply unit 140 includes a plurality of air bubble supply pipes 142. In the example of FIG. 1, the air bubble supply unit 140 includes eight air bubble supply pipes 142. The number of air bubble supply pipes 142 is not particularly limited. The air bubble supply pipe 142 is, for example, a bubbler pipe.

A material of the air bubble supply pipe 142 is quartz or synthetic resin.

As illustrated in FIGS. 1 and 2, each of the plurality of air bubble supply pipes 142 includes a plurality of air bubble holes 141a. In the example of FIG. 1, the air bubble holes 141a are directed upward along the vertical direction Z. The air bubble supply pipe 142 supplies the air bubbles BB into the etching liquid LQ by discharging the nitrogen gas supplied to the air bubble supply unit 140 from the air bubble holes 141a. That is, the air bubble supply pipe 142 receives the supply of the nitrogen gas and supplies the air bubbles BB to the etching liquid LQ.

The plurality of air bubble supply pipes 142 are disposed substantially in parallel with each other in the width direction X in the processing tank 110. The air bubble supply pipes 142 extend along the front-rear direction Y. In each air bubble supply pipe 142, the plurality of air bubble holes 141a are formed at intervals in the front-rear direction X.

Specifically, each of the plurality of air bubble supply pipes 142 supplies the air bubbles BB from each of the plurality of air bubble holes 141a to the etching liquid LQ from below the substrate W in a state where the substrate W is immersed in the etching liquid LQ. Therefore, the etching efficiency can be improved as compared with a case of not supplying the air bubbles BB. As a result, the substrate W immersed in the etching liquid LQ can be effectively processed with the etching liquid LQ.

The air bubble discharge amount adjustment unit 145 adjusts the discharge amount of the air bubbles BB to be supplied to the etching liquid LQ by adjusting the discharge amount of the air bubbles BB (that is, the discharge amount of the nitrogen gas) discharged from the air bubble holes 141a for each air bubble supply pipe 142. The adjustment of the discharge amount of the nitrogen gas includes making the discharge amount of the nitrogen gas constant, increasing the discharge amount of the nitrogen gas, decreasing the discharge amount of the nitrogen gas, and making the discharge amount of the nitrogen gas zero. In the first embodiment, the air bubble discharge amount adjustment unit 145 switches each air bubble supply pipe 142 between supply and supply stop of the nitrogen gas to the air bubble holes 141a. In other words, the air bubble discharge amount adjustment unit 145 switches each air bubble supply pipe 142 between supply and supply stop of the air bubbles BB discharged from the air bubble holes 141a into the processing tank 110.

Specifically, as illustrated in FIG. 2, the air bubble discharge amount adjustment unit 145 includes a plurality of gas flow rate adjustment mechanisms 146 corresponding to the plurality of air bubble supply pipes 142, respectively. The plurality of supply pipes P4 are provided corresponding to the plurality of gas flow rate adjustment mechanisms 146, respectively. One end of each supply pipe P4 is connected to the corresponding air bubble supply pipe 142. The other ends of the supply pipes P4 are connected to the common pipe P3. The common pipe P3 is connected to a gas supply source 143.

The plurality of gas flow rate adjustment mechanisms 146 are disposed in the plurality of supply pipes P4, respectively. Each gas flow rate adjustment mechanism 146 supplies the nitrogen gas supplied from the gas supply source 143 and the common pipe P3 to the corresponding air bubble supply pipe 142 through the corresponding supply pipe P4. The gas flow rate adjustment mechanism 146 also adjusts the flow rate of the nitrogen gas to be supplied to the corresponding air bubble supply pipe 142. As a result, the discharge amount of the air bubbles BB supplied to the etching liquid LQ is adjusted in each air bubble supply pipe 142. In the first embodiment, the gas flow rate adjustment mechanism 146 switches between the supply and supply stop of the nitrogen gas to the corresponding air bubble supply pipe 142. In other words, in the first embodiment, the gas flow rate adjustment mechanism 146 switches between the supply and supply stop of the air bubbles BB from the corresponding air bubble supply pipe 142 to the etching liquid LQ of the processing tank 110.

Specifically, as illustrated in FIG. 2, the gas flow rate adjustment mechanism 146 includes an adjustment valve b1, a flow meter b2, a filter b3, and a valve b4. The adjustment valve b1, the flow meter b2, the filter b3, and the valve b4 are disposed in the supply pipe P4 in this order from the upstream to the downstream of the supply pipe P4.

The adjustment valve b1 adjusts the opening degree of the supply pipe P4 to adjust the flow rate of the nitrogen gas flowing through the supply pipe P4, and adjust the flow rate of the nitrogen gas supplied to the air bubble supply pipe 142. The flow meter b2 measures the flow rate of the nitrogen gas flowing through the supply pipe P4. The adjustment valve b1 adjusts the flow rate of the nitrogen gas on the basis of a measurement result of the flow meter b2. For example, a mass flow controller may be provided instead of the adjustment valve b1 and the flow meter b2.

The filter b3 removes foreign substances from the nitrogen gas flowing through the supply pipe P4. The valve b4 opens and closes the supply pipe P4. That is, the valve b4 switches between the supply and supply stop of the nitrogen gas from the supply pipe P4 to the air bubble supply pipe 142.

Returning to FIG. 1, the substrate processing apparatus 100 includes a control device 160. The control device 160 controls processing on the substrate W. The processing on the substrate W includes etching the substrate W. The control device 160 controls each component of the substrate processing apparatus 100. For example, the control device 160 controls the substrate holder 120, the etching liquid supply unit 130, the air bubble supply unit 140, and the drainage unit 150.

The control device 160 includes a controller 161 and a memory 162. The controller 161 includes a processor such as a central processing unit (CPU) and a graphics processing unit (GPU). The memory 162 includes a storage device, and stores data and a computer program. The processor of the controller 161 executes the computer program stored in the storage device of the memory 162 to control each component of the substrate processing apparatus 100. For example, the memory 162 includes a main storage device such as a semiconductor memory and an auxiliary storage device such as a semiconductor memory and a hard disk drive. The memory 162 may include a removable medium such as an optical disk. The memory 162 may be, for example, a non-transitory computer-readable storage medium. The control device 160 may include an input device and a display device.

The controller 161 corresponds to a “controller” of the present invention.

### 1-3. Control Example of Supply of Etching Liquid and Air Bubbles

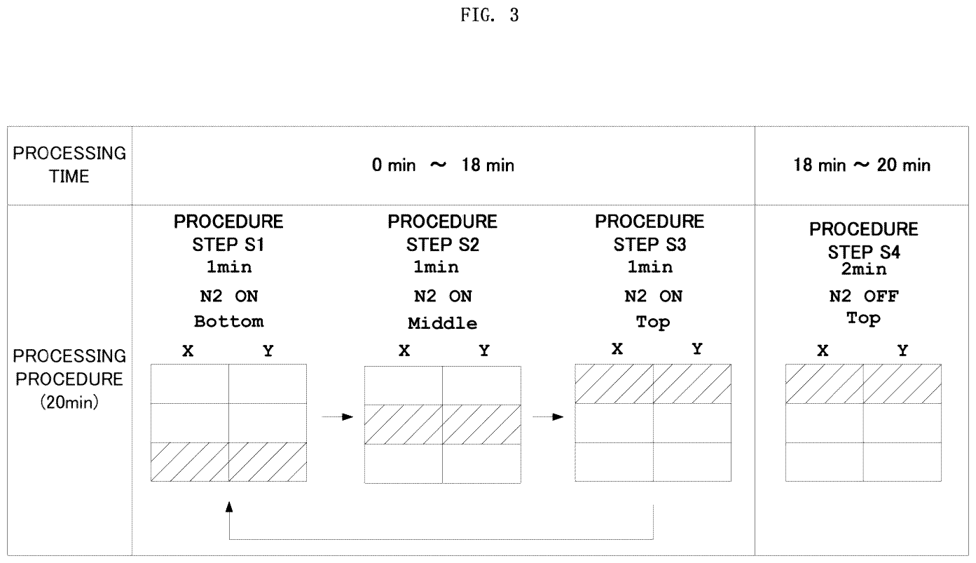

Next, a control example of supply of the etching liquid LQ and the air bubbles BB will be described with reference to FIG. 3.

FIG. 3 is a drawing illustrating an example of a processing procedure of the etching liquid supply unit 130 and the air bubble supply unit 140.

The total processing time is, for example, 20 minutes. From the start of the processing to 18 minutes, for example, procedure steps S1, S2, and S3 are repeated in this order. From 18 minutes to 20 minutes after the start of the processing, procedure step S4 is performed.

In procedure step S1, the bottom etching liquid supply units 133X and 133Y supply the etching liquid LQ to the substrate W. The supply of the etching liquid LQ from the bottom etching liquid supply units 133X and 133Y is illustrated by hatching bottom two blocks among two blocks stacked in three stages. The processing time of procedure step S1 is, for example, 1 minute. In procedure step S1, the air bubble supply unit 140 supplies the air bubbles BB to the substrate W. In the drawing, supplying the etching liquid LQ from the bottom etching liquid supply units 133X and 133Y is denoted as “Bottom”. In the drawing, supplying the air bubbles BB to the substrate W is denoted as “N2 ON”.

In procedure step S2, the lower etching liquid supply units 132X and 132Y supply the etching liquid LQ to the substrate W. The supply of the etching liquid LQ from the lower etching liquid supply units 132X and 132Y is illustrated by hatching middle two blocks among the two blocks stacked in three stages. The processing time of procedure step S2 is, for example, 1 minute. In procedure step S2, the air bubble supply unit 140 supplies the air bubbles BB to the substrate W. In the drawing, supplying the etching liquid LQ from the lower etching liquid supply units 132X and 132Y is denoted as “Middle”.

In procedure step S3, the upper etching liquid supply units 131X and 131Y supply the etching liquid LQ to the substrate W. The supply of the etching liquid LQ from the upper etching liquid supply units 131X and 131Y is illustrated by hatching uppermost two blocks among the two blocks stacked in three stages. The processing time of procedure step S3 is, for example, 1 minute. In procedure step S3, the air bubble supply unit 140 supplies the air bubbles BB to the substrate W. In the drawing, supplying the etching liquid LQ from the upper etching liquid supply units 131X and 131Y is denoted as “Top”.

Thereafter, procedure steps S1, S2, and S3 are repeated in this order from the start of the processing to 18 minutes. The bottom etching liquid supply units 133X and 133Y supply the etching liquid LQ to the substrate W with the air bubbles BB being supplied to the substrate W for a total of 6 minutes.

The lower etching liquid supply units 132X and 132Y supply the etching liquid LQ to the substrate W with the air bubbles BB being supplied to the substrate W for a total of 6 minutes.

The upper etching liquid supply units 131X and 131Y supply the etching liquid LQ to the substrate W with the air bubbles BB being supplied to the substrate W for a total of 6 minutes.

Procedure step S4 is performed from 18 minutes to 20 minutes after the start of the processing. Specifically, in procedure step S4, the upper etching liquid supply units 131X and 131Y supply the etching liquid LQ to the substrate W. The processing time of procedure step S4 is 2 minutes. In procedure step S4, the air bubble supply unit 140 does not supply the air bubbles BB to the substrate W. In the drawing, not supplying the air bubbles BB to the substrate W is denoted as “N2 OFF”.

The upper etching liquid supply units 131X and 131Y supply the etching liquid LQ to the substrate W with no air bubbles BB being supplied to the substrate W for another 2 minutes. That is, the upper etching liquid supply units 131X and 131Y supply the etching liquid LQ to the substrate W with no air bubbles BB being supplied to the substrate W for a total of 8 minutes.

### 1-4. State in Processing Tank in which Supply of Etching Liquid and Air Bubbles is Controlled

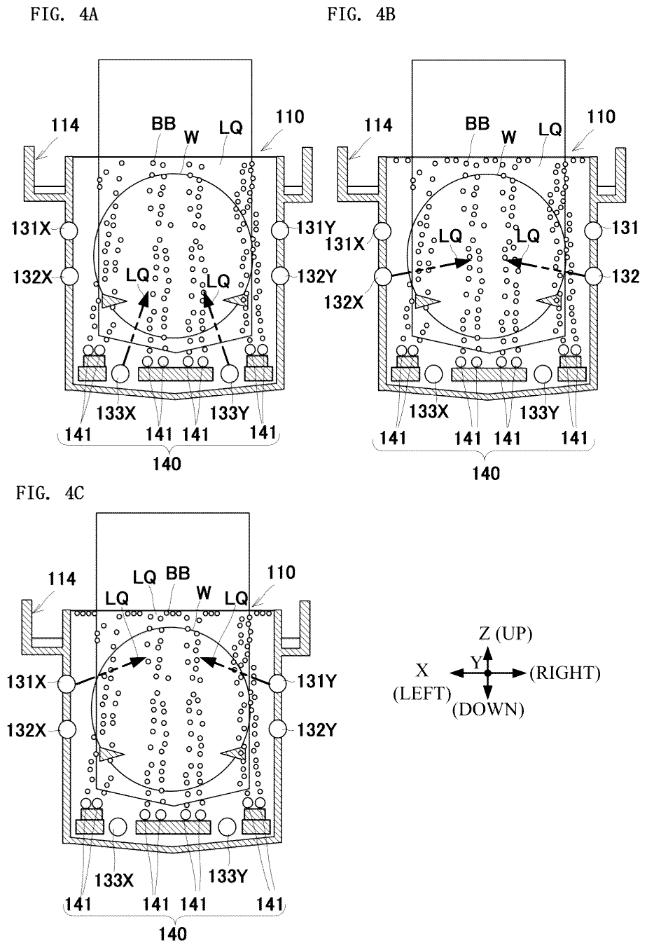

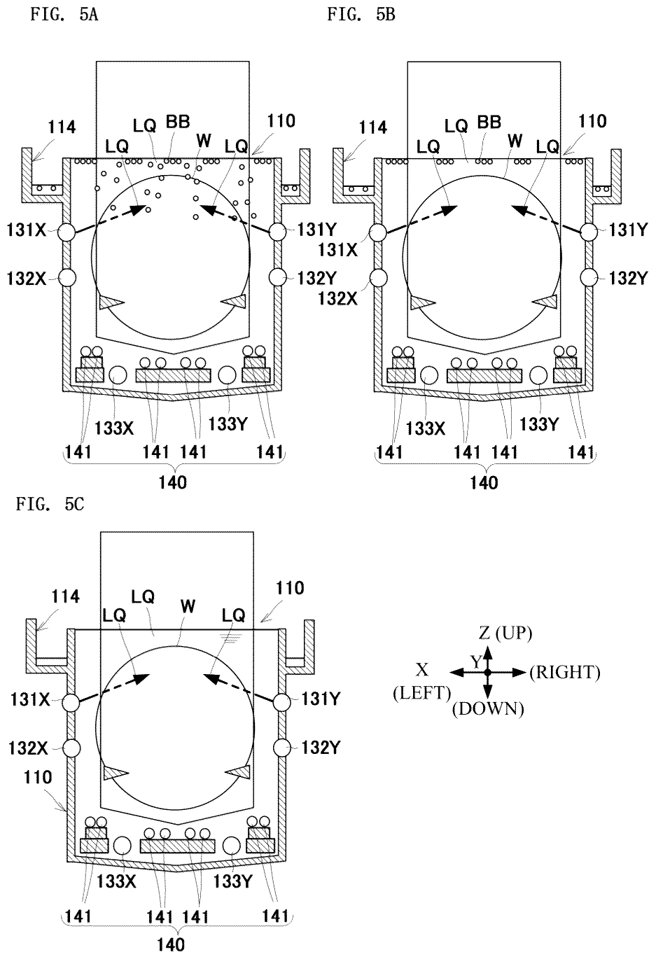

With reference to FIGS. 4A to 5C, a state in the processing tank 110 in which the supply of the etching liquid LQ and the air bubbles BB is controlled by the etching liquid supply unit 130 and the air bubble supply unit 140 according to the above-described processing procedure will be described.

FIGS. 4A to 4C are drawings illustrating the states in the processing tank 110 in which the supply of the etching liquid LQ and the air bubbles BB is controlled according to procedure steps S1 to S3 illustrated in FIG. 3.

FIGS. 4A to 4C illustrate a state in which the supply of the etching liquid LQ and the air bubbles BB at an early timing not long after the start of the processing (for example, from 1 minute to 3 minutes after the start of the processing) is controlled.

As illustrated in FIG. 4A, in procedure step S1, the air bubble supply unit 140 supplies the air bubbles BB from the bottom portion of the processing tank 110. The bottom etching liquid supply units 133X and 133Y supply the etching liquid LQ from positions relatively closer to the side walls in the bottom portion of the processing tank 110 toward a region around the center of the lower portion of the substrate W. The flow of the etching liquid LQ supplied from the bottom etching liquid supply units 133X and 133Y, which is indicated by the two-dot chain lines, is changed by the air bubbles BB. That is, the flow of the etching liquid LQ is diffused by the air bubbles BB. Therefore, the etching liquid LQ is easily supplied to the region around the center of the lower portion of the substrate W and its peripheral portion.

As illustrated in FIG. 4B, in procedure step S2, the air bubble supply unit 140 supplies the air bubbles BB from the bottom portion of the processing tank 110. The lower etching liquid supply units 132X and 132Y supply the etching liquid LQ slightly obliquely upward from the height around the middle in the height direction of the first side wall 116 and the second side wall 117 toward the intermediate portion of the substrate W. The flow of the etching liquid LQ supplied from the lower etching liquid supply units 132X and 132Y, which is indicated by the two-dot chain lines, is changed by the air bubbles BB. That is, the flow of the etching liquid LQ is diffused by the air bubbles BB. Therefore, the etching liquid LQ is easily supplied to the intermediate portion of the substrate W and its peripheral portion.

As illustrated in FIG. 4C, in procedure step S3, the air bubble supply unit 140 supplies the air bubbles BB from the bottom portion of the processing tank 110. The upper etching liquid supply units 131X and 131Y supply the etching liquid LQ obliquely upward from positions slightly higher than the middle in the height direction of the first side wall 116 and the second side wall 117 toward the upper portion of the substrate W. The flow of the etching liquid LQ supplied from the upper etching liquid supply units 131X and 131Y, which is indicated by the two-dot chain lines, is changed by the air bubbles BB. That is, the flow of the etching liquid LQ is diffused by the air bubbles BB. Therefore, the etching liquid LQ is easily supplied to the opposite outer sides of the upper portion of the substrate W and its peripheral portion.

The air bubbles BB supplied from the air bubble supply unit 140 at this timing and the air bubbles BB supplied from the air bubble supply unit 140 by this timing gather around a surface layer of the etching liquid LQ. The air bubbles BB supplied from the air bubble supply unit 140 by this timing are the air bubbles BB floating around the surface layer of the etching liquid LQ before they overflow into the outer tank 114. That is, there are more air bubbles BB around the surface layer of the etching liquid LQ than in a lower layer.

Reference is made to FIGS. 5A to 5C. FIGS. 5A to 5C are drawings illustrating the states in the processing tank 110 in which the supply of the etching liquid LQ and the air bubbles BB is controlled according to procedure step S4.

As illustrated in FIG. 5A, in procedure step S4, the supply of the air bubbles BB is stopped. Therefore, no air bubbles BB are newly supplied from the lower layer of the etching liquid LQ. The etching liquid LQ is supplied from the upper etching liquid supply units 131X and 131Y. Therefore, the air bubbles BB gradually decrease. The flow of the etching liquid LQ supplied from the upper etching liquid supply units 131X and 131Y, which is indicated by the two-dot chain lines, is less likely to be changed by the air bubbles BB. That is, the flow of the etching liquid LQ is less likely to be diffused by the air bubbles BB. Therefore, the fresh etching liquid LQ is easily supplied to the upper portion of the substrate W.

As illustrated in FIG. 5B, in procedure step S4, the etching liquid LQ not including the air bubbles BB is continuously supplied from the upper etching liquid supply units 131X and 131Y. This further reduces the air bubbles BB. Therefore, the flow of the etching liquid LQ supplied from the upper etching liquid supply units 131X and 131Y, which is indicated by the two-dot chain lines, is further less likely to be changed by the air bubbles BB. That is, the flow of the etching liquid LQ is further less likely to be diffused by the air bubbles BB. Therefore, the fresh etching liquid LQ is more easily supplied to the upper portion of the substrate W.

As illustrated in FIG. 5C, in procedure step S4, the etching liquid LQ not including the air bubbles BB is continuously supplied from the upper etching liquid supply units 131X and 131Y. As a result, for example, there are almost no air bubbles BB. Therefore, the flow of the etching liquid LQ supplied from the upper etching liquid supply units 131X and 131Y, which is indicated by the two-dot chain lines, is unlikely to be changed by the air bubbles BB. That is, the flow of the etching liquid LQ is unlikely to be diffused by the air bubbles BB. Therefore, the fresh etching liquid LQ is easily intensively supplied to the upper portion of the substrate W. The etching liquid LQ is continuously supplied to the upper portion of the substrate W in this state, so that the etching rate of the substrate W is improved.

### 1-5. Uniformity of Etching in Substrate Surface

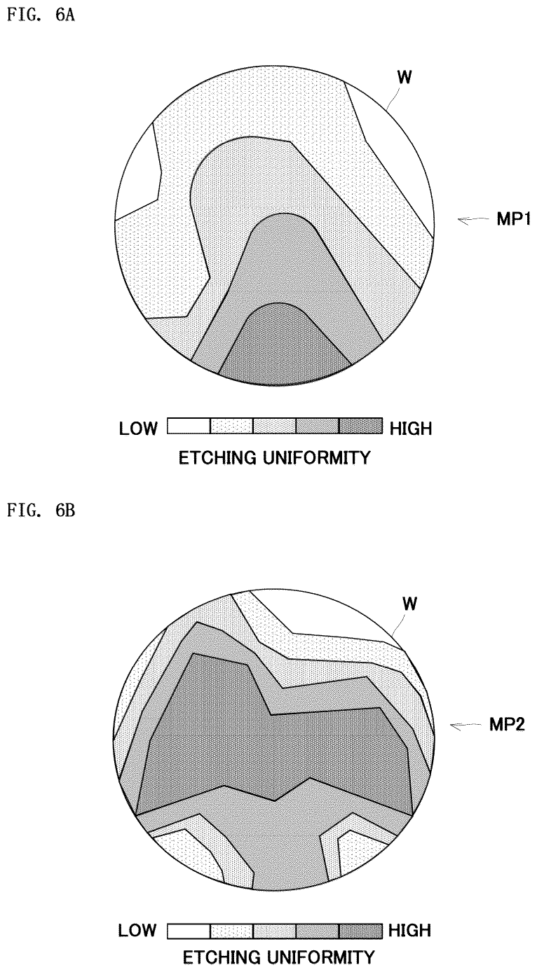

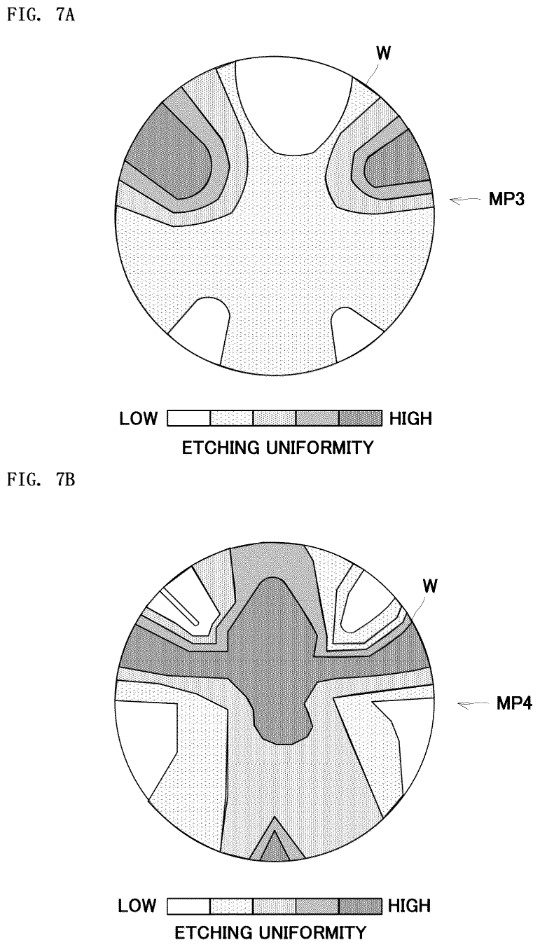

Next, the uniformity of etching in the surface of the substrate W will be described with reference to FIGS. 6A to 7B.

Reference is made to FIGS. 6A and 6B. FIGS. 6A and 6B are map images MP1 and MP2 illustrating the uniformity of etching in the surface of the substrate W in a case where the supply of the etching liquid LQ and the air bubbles BB is controlled according to procedure steps S1 and S2.

The uniformity of etching is calculated on the basis of the etching rate obtained for each section by dividing the surface of the substrate W. The etching rate is a value obtained by dividing the etching amount by the etching time. A region having high etching uniformity has a high etching rate and is easily etched. A region having low etching uniformity has a low etching rate and is difficult to be etched.

In the map image MP1, the denser the dots, the higher the etching uniformity. A white region with no dot indicates a region with the lowest etching uniformity. In practice, the etching uniformity has gradation in the map images MP1, MP2, MP3, and MP4, but the etching uniformity is shown in four stages in a simplified manner. The same applies to the map images MP2, MP3, and MP4 described later.

FIG. 6A is the map image MP1 illustrating the uniformity of etching in the surface of the substrate W in a case where the etching liquid LQ is continuously supplied from the bottom etching liquid supply units 133X and 133Y in a state where the air bubbles BB are supplied as in procedure step S1.

As illustrated in FIG. 6A, in the map image MP1, the etching uniformity around the center of a bottom portion of the substrate W is the highest. Then, the etching uniformity in most of the peripheral portion around the center of the bottom portion of the substrate W is also relatively high.

There is a portion having the lowest etching uniformity on the opposite outer sides of the upper portion of the substrate W. This may be affected by a distance from the bottom etching liquid supply units 133X and 133Y.

FIG. 6B is the map image MP2 illustrating the uniformity of etching in the surface of the substrate W in a case where the etching liquid LQ is continuously supplied from the lower etching liquid supply units 132X and 132Y in a state where the air bubbles BB are supplied as in procedure step S2.

As illustrated in FIG. 6B, in the map image MP2, the etching uniformity in the intermediate portion of the substrate W is the highest. Then, the etching uniformity in most of the peripheral portion of the intermediate portion of the substrate W is also relatively high.

There is a portion having the lowest etching uniformity in the uppermost portion of the substrate W. This may be affected by a distance from the lower etching liquid supply units 132X and 132Y.

Reference is made to FIGS. 7A and 7B. FIGS. 7A and 7B are map images MP3 and MP4 illustrating the uniformity of etching in the surface of the substrate W in a case where the supply of the etching liquid LQ and the air bubbles BB is controlled according to procedure steps S3 and S4.

FIG. 7A is the map image MP3 illustrating the uniformity of etching in the surface of the substrate W in a case where the etching liquid LQ is continuously supplied from the upper etching liquid supply units 131X and 131Y in a state where the air bubbles BB are supplied as in procedure step S3.

As illustrated in FIG. 7A, in the map image MP3, the etching uniformity on the opposite outer sides of the upper portion of the substrate W is the highest. Then, the etching uniformity in most of the peripheral portion of the opposite outer sides of the upper portion of the substrate W is also relatively high.

As described above, by supplying the etching liquid LQ during a period in which the air bubbles BB are supplied, the etching uniformity can be improved as compared with a case where only the etching liquid LQ is supplied without supplying the air bubbles BB. In a case where only the etching liquid LQ is supplied without supplying the air bubbles BB, a region having a high etching rate is smaller than that in a case where the etching liquid LQ is supplied during the period in which the air bubbles BB are supplied.

Here, the present inventors have found that there is a region having a low etching rate despite the etching liquid LQ being supplied during the period in which the air bubbles BB are supplied. Specifically, this region is around the center of the upper portion of the substrate. As illustrated in FIG. 7A, the center of the upper portion of the substrate W has a low etching rate. Therefore, the center of the upper portion of the substrate W has the lowest etching uniformity.

In FIG. 7A, a portion having the lowest etching uniformity is also present on the opposite outer sides of the lower portion of the substrate W. This may be affected by the fact that the opposite outer sides of the lower portion are far from the upper etching liquid supply units 131X and 131Y.

FIG. 7B is the map image MP4 illustrating the uniformity of etching in the surface of the substrate W in a case where the etching liquid LQ is continuously supplied from the upper etching liquid supply units 131X and 131Y in a state where the supply of the air bubbles BB is stopped as in procedure step S4.

As illustrated in FIG. 7B, in the map image MP4, there is a region having the highest etching uniformity on the opposite outer sides of the upper portion of the substrate W. In addition, the region having the highest etching uniformity also extends to the center of the upper portion of the substrate W. Furthermore, the region having the highest etching uniformity also extends to the uppermost portion of the substrate W and its peripheral portion.

As described above, it can be understood that the etching rate in the upper portion of the substrate W is improved as the etching liquid LQ is continuously supplied from the upper etching liquid supply units 131X and 131Y in a state where the supply of the air bubbles BB is stopped. Therefore, it can be understood that the etching uniformity is improved by performing procedure step S4 after procedure steps S1, S2, and S3 described above.

### 1-6. Substrate Processing Method According to First Embodiment

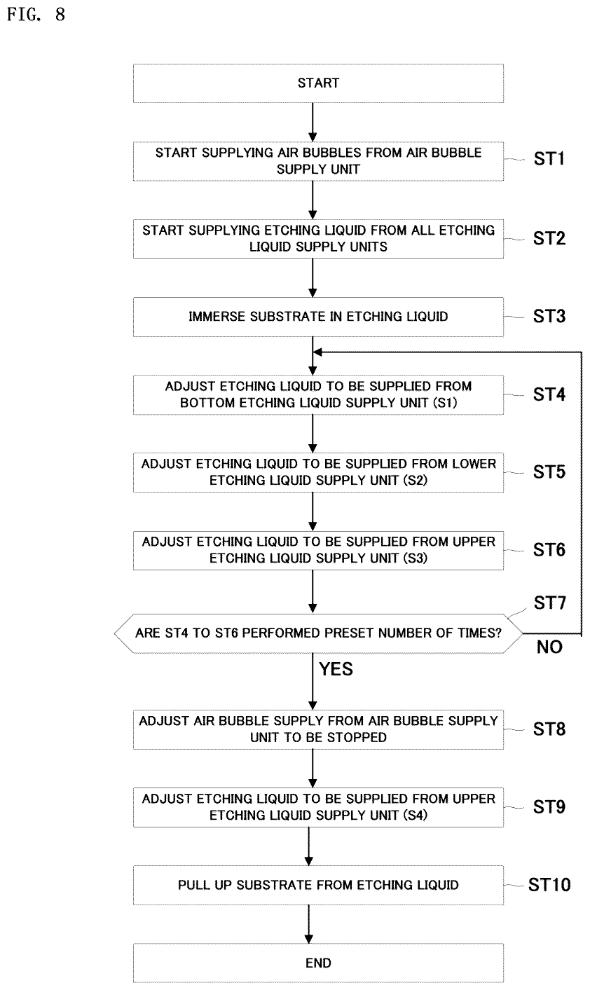

Next, a substrate processing method according to the first embodiment will be described with reference to FIG. 8. The substrate processing method is executed by the substrate processing apparatus 100. FIG. 8 is a flowchart illustrating the substrate processing method according to the first embodiment.

As illustrated in FIG. 8, the substrate processing method includes steps ST1 to ST10. Steps ST1 to ST10 are executed under the control of the controller 161.

### (Step ST1: Air Bubble Supply Step)

First, in step ST1, the air bubble supply unit 140 starts supplying the plurality of air bubbles BB to the etching liquid LQ stored in the processing tank 110. Step ST1 corresponds to an example of an “air bubble supply step” (that is, “supplying the plurality of air bubbles into the processing tank in which the substrate is immersed” and the same applies hereinafter) of the present invention.

### (Step ST2: Etching Liquid Supply Step)

Next, in step ST2, all the units of the etching liquid supply unit 130 start supplying the etching liquid LQ toward the etching liquid LQ stored in the processing tank 110. The etching liquid LQ is supplied in a state of being heated to a temperature suitable for etching (for example, 90° C. to 100° C.). The temperature of the etching liquid LQ is not limited to this example, but the temperature of the etching liquid LQ is higher than the outside air, that is, the temperature in a chamber accommodating the processing tank 110. By supplying the etching liquid LQ from all the units of the etching liquid supply unit 130, the temperature of the etching liquid LQ stored in the processing tank 110 can be made uniform.

### (Step ST3: Immersion Step)

Next, in step ST3, the substrate holder 120 immerses the substrate W in the etching liquid LQ stored in the processing tank 110. Step ST3 corresponds to an example of an “immersion step” (that is, “immersing the substrate held by the substrate holder in the etching liquid stored in the processing tank” and the same applies hereinafter) of the present invention.

Next, in steps ST4 to ST6, the behavior of the air bubbles BB is controlled by supplying the etching liquid LQ from the etching liquid supply unit 130 toward the substrate W while switching the respective units of the etching liquid supply unit 130.

### (Step ST4: Bottom Etching Liquid Supply Step (Etching Liquid Discharge Amount Adjustment Step))

Specifically, in step ST4, the bottom etching liquid supply units 133X and 133Y supply the etching liquid LQ toward the substrate W. That is, the etching liquid discharge amount adjustment units 135 adjust the discharge amount of the etching liquid LQ so as to continue the supply of the etching liquid LQ from the bottom etching liquid supply units 133X and 133Y toward the substrate W. The etching liquid discharge amount adjustment units 135 also adjust the discharge amount of the etching liquid LQ so as to stop the supply of the etching liquid LQ from the upper etching liquid supply units 131X and 131Y and the lower etching liquid supply units 132X and 132Y toward the substrate W.

Step ST4 corresponds to procedure step S1 described above. Step ST4 corresponds to an example of an “etching liquid supply step” (that is, “supplying the etching liquid into the processing tank in which the substrate is immersed” and the same applies hereinafter) of the present invention. Step ST4 also corresponds to an example of an etching liquid discharge amount adjustment step.

### (Step ST5: Lower Etching Liquid Supply Step (Etching Liquid Discharge Amount Adjustment Step))

In step ST5, the lower etching liquid supply units 132X and 132Y supply the etching liquid LQ toward the substrate W. That is, the etching liquid discharge amount adjustment units 135 adjust the discharge amount of the etching liquid LQ so as to start the supply of the etching liquid LQ from the lower etching liquid supply units 132X and 132Y toward the substrate W. The etching liquid discharge amount adjustment units 135 also adjust the discharge amount of the etching liquid LQ so as to continue the supply stop of the etching liquid LQ from the upper etching liquid supply units 131X and 131Y toward the substrate W. The etching liquid discharge amount adjustment units 135 also adjust the discharge amount of the etching liquid LQ so as to stop the supply of the etching liquid LQ from the bottom etching liquid supply units 133X and 133Y toward the substrate W.

Step ST5 corresponds to procedure step S2 described above. Step ST5 corresponds to an example of the “etching liquid supply step” of the present invention. Step ST5 also corresponds to an example of the etching liquid discharge amount adjustment step.

### (Step ST6: Upper Etching Liquid Supply Step (Etching Liquid Discharge Amount Adjustment Step))

In step ST6, the upper etching liquid supply units 131X and 131Y supply the etching liquid LQ toward the substrate W. That is, the etching liquid discharge amount adjustment units 135 adjust the discharge amount of the etching liquid LQ so as to start the supply of the etching liquid LQ from the upper etching liquid supply units 131X and 131Y toward the substrate W. The etching liquid discharge amount adjustment units 135 also adjust the discharge amount of the etching liquid LQ so as to continue the supply stop of the etching liquid LQ from the bottom etching liquid supply units 133X and 133Y toward the substrate W. The etching liquid discharge amount adjustment units 135 also adjust the discharge amount of the etching liquid LQ so as to stop the supply of the etching liquid LQ from the lower etching liquid supply units 132X and 132Y toward the substrate W.

Step ST6 corresponds to procedure step S3 described above. Step ST6 corresponds to an example of the “etching liquid supply step” of the present invention. Step ST6 also corresponds to an example of the etching liquid discharge amount adjustment step.

In step ST7, the controller 161 determines whether the processing of steps ST4 to ST6 described above has been performed a preset number of times. The preset number of times is stored in the memory 162 of the control device 160, for example. The preset number of times may be input by an operator via an input unit provided in the substrate processing apparatus 100.

In a case where the preset number of times has not been reached, the process returns to step ST4. In a case where the preset number of times has been reached, the process proceeds to step ST8.

Step ST7 corresponds to an example of the “etching liquid supply step” of the present invention. Step ST7 also corresponds to an example of the etching liquid discharge amount adjustment step.

### (Step ST8: Air Bubble Supply Step (Air Bubble Adjustment Step))

In step ST8, the air bubble supply unit 140 adjusts the discharge of the air bubbles BB. Specifically, the air bubble discharge amount adjustment unit 145 adjusts the discharge of the air bubbles BB. In step ST8, the discharge amount of the air bubbles BB is adjusted so that the discharge amount of the air bubbles BB during a period in which the etching liquid LQ is discharged from the upper discharge hole 131a (period in which step ST9 described below is executed) is smaller than the discharge amount of the air bubbles BB during a period in which the etching liquid LQ is discharged from the lower discharge hole 132a (period in which step ST5 described above is executed).

The “period in which the etching liquid LQ is discharged from the upper discharge hole 131a” and the “period in which the etching liquid LQ is discharged from the lower discharge hole 132a” are compared using periods of the same length. That is, when the “period in which the etching liquid LQ is discharged from the upper discharge hole 131a” is 2 minutes, the “period in which the etching liquid LQ is discharged from the lower discharge hole 132a” is also 2 minutes. The “period in which the etching liquid LQ is discharged from the lower discharge hole 132a” in this case is a period obtained by doubling the period in which step ST5 is executed.

For example, in step ST8, the air bubble supply unit 140 stops the supply of the air bubbles BB. That is, the discharge amount of the air bubbles BB during the period in which the etching liquid LQ is discharged from the upper discharge hole 131a in step ST9 described below is 0 or almost 0. The discharge amount of the air bubbles BB during the period in which the etching liquid LQ is discharged from the upper discharge hole 131a (period in which step ST9 described below is executed) is smaller than the discharge amount of the air bubbles BB during the period in which the etching liquid LQ is discharged from the lower discharge hole 132a.

Step ST8 is an example of the “air bubble supply step” of the present invention. Step ST8 is an example of an “air bubble discharge amount adjustment step” of the present invention.

In step ST9, the upper etching liquid supply units 131X and 131Y supply the etching liquid LQ. As a result, the air bubbles BB in the processing tank 110 are reduced. The etching liquid LQ supplied from the upper etching liquid supply units 131X and 131Y is supplied to the upper portion of the substrate W without being subjected to the diffusion action by the air bubbles BB. As a result, the etching rate in the upper portion of the substrate W is improved. After step ST9 is finished, the process proceeds to step ST10.

In step ST10, the substrate holder 120 pulls up the substrate W from the etching liquid LQ. As a result, the substrate processing method ends.

### 1-7. Effects of First Embodiment

As described above, according to the substrate processing apparatus 100 of the first embodiment, the substrate processing apparatus 100 processes the substrate W. The substrate processing apparatus 100 includes the processing tank 110, the substrate holder 120, the etching liquid supply unit 130, the air bubble supply unit 140, and the controller 161. The processing tank 110 stores the etching liquid LQ for etching the substrate W. The substrate holder 120 holds the substrate W and immerses the substrate W in the etching liquid LQ stored in the processing tank 110. The etching liquid supply unit 130 is disposed in the processing tank 110 and supplies the etching liquid LQ into the processing tank 110. The etching liquid supply unit 130 includes at least the upper discharge hole 131a and the lower discharge hole 132a. In the upper discharge hole 131a, the direction in which the etching liquid LQ is discharged is directed to the upper portion of the substrate W. The lower discharge hole 132a is disposed below the upper discharge hole 131a and discharges the etching liquid LQ. The air bubble supply unit 140 is disposed in the processing tank 110 and supplies the plurality of air bubbles BB to the etching liquid LQ from below the substrate W. Here, the air bubbles BB supplied from the air bubble supply unit 140 gather around the upper portion of the processing tank 110, possibly resulting in a decrease in the temperature of the etching liquid LQ around the upper portion of the processing tank 110. This decrease in the temperature of the etching liquid LQ around the upper portion of the processing tank 110 may lead to a decrease in the etching rate in the upper portion of the substrate W.

Therefore, the substrate processing apparatus 100 according to the first embodiment is further configured as follows. The controller 161 controls the processing on the substrate W. The controller 161 controls the etching liquid supply unit 130 to adjust the discharge amount of the etching liquid LQ so that the discharge amount of the etching liquid LQ discharged from the upper discharge hole 131a is larger than the discharge amount of the etching liquid LQ discharged from the lower discharge hole 132a in a part of a period in which the substrate W is etched. As a result, even if a situation occurs in which the air bubbles BB are likely to gather around the upper portion of the processing tank 110, the etching liquid LQ is reliably easily supplied to the upper portion of the substrate W. Therefore, the etching liquid LQ easily etches the upper portion of the substrate W. That is, the etching rate in the upper portion of the substrate W increases. As a result, the etching uniformity in the surface of the substrate W is improved. In this manner, the substrate processing apparatus 100 according to the first embodiment can reduce processing unevenness in the surface of the substrate W.

In the substrate processing apparatus 100, the processing tank 110 includes the bottom portion 115A and the side wall portion 115B that extends upward from the bottom portion 115A. The side wall portion 115B includes the first side wall 116 and the second side wall 117 that faces the first side wall 116. The upper discharge hole 131a and the lower discharge hole 132a are provided on each of the first side wall 116 side and the second side wall 117 side. That is, the etching liquid LQ is supplied from the opposite sides of the first side wall 116 side and the second side wall 117 side toward the upper portion of the substrate W. Therefore, the etching liquid is more easily supplied to the upper portion of the substrate.

In the first embodiment, the etching liquid supply pipe having the upper discharge hole 131a and the etching liquid supply pipe having the lower discharge hole 132a are provided on each of the first side wall 116 and the second side wall 117. The upper discharge hole 131a and the lower discharge hole 132a may be directly provided in each of the first side wall 116 and the second side wall 117. The etching liquid supply pipe having the upper discharge hole 131a and the etching liquid supply pipe having the lower discharge hole 132a may be provided slightly away from each of the first side wall 116 and the second side wall 117.

The controller 161 controls the etching liquid supply unit 130 to adjust the discharge of the etching liquid LQ so that the discharge amount of the etching liquid LQ discharged from the upper discharge hole 131a is larger than the discharge amount (discharge amount=0) of the etching liquid LQ discharged from the lower discharge hole 132a in a part of the period in which the substrate W is etched (for example, the remaining 2 minutes). The controller 161 also controls the etching liquid supply unit 130 to adjust the discharge of the etching liquid LQ so that the discharge amount of the etching liquid LQ discharged from the upper discharge hole 131a is larger than the discharge amount (discharge amount=0) of the etching liquid LQ discharged from the bottom discharge hole 133a in a part of the period in which the substrate W is etched (for example, the remaining 2 minutes). Therefore, the etching liquid LQ is more easily supplied to the upper portion of the substrate W in at least a part of the period in which the substrate W is etched.

In the first embodiment, the etching liquid supply pipe having the bottom discharge hole 133a is provided on the bottom portion 115A. The bottom discharge hole 133a may be directly provided in the bottom portion 115A. The etching liquid supply pipe having the bottom discharge hole 133a may be provided slightly away from the bottom portion 115A.

In the substrate processing apparatus 100, the controller 161 controls the etching liquid supply unit 130 to adjust the discharge amount of the etching liquid LQ so that the period in which the etching liquid LQ is discharged from the upper discharge hole 131a is longer than the period in which the etching liquid LQ is discharged from the lower discharge hole 132a. Therefore, it is easy to make the discharge amount of the etching liquid LQ discharged from the upper discharge hole 131a larger than the discharge amount of the etching liquid LQ discharged from the lower discharge hole 132a.

The controller 161 controls the etching liquid supply unit 130 to adjust the discharge amount of the etching liquid LQ so that the period in which the etching liquid LQ is discharged from the upper discharge hole 131a is longer than a period in which the etching liquid LQ is discharged from the bottom discharge hole 133a. Therefore, it is easy to make the discharge amount of the etching liquid LQ discharged from the upper discharge hole 131a larger than the discharge amount of the etching liquid LQ discharged from the bottom discharge hole 133a.

In the substrate processing method according to the first embodiment, the substrate processing method is a method of processing the substrate. The substrate processing method includes the immersion step (for example, step ST3), the etching liquid supply step (for example, steps ST2, ST4, ST5, ST6, and ST9), and the air bubble supply step (steps ST1 and ST8). In the immersion step, the substrate W held by the substrate holder 120 is immersed in the etching liquid LQ stored in the processing tank 110 in step ST3. In the etching liquid supply step, the etching liquid LQ is supplied into the processing tank 110 in which the substrate W is immersed in steps ST4 to ST6. In the air bubble supply step, the plurality of air bubbles BB are supplied into the processing tank 110 in which the substrate W is immersed in step ST1 during the execution of steps ST4 to ST6. When the air bubbles BB are discharged, a situation occurs in which the air bubbles are likely to gather around the upper portion of the processing tank 110. In the etching liquid supply step, in step ST9, the discharge amount of the etching liquid LQ is adjusted so that the discharge amount of the etching liquid LQ discharged toward the upper portion of the substrate W is larger than the discharge amount of the etching liquid LQ discharged toward the lower portion of the substrate W in a part of the period in which the substrate W is etched (period in which step ST9 is executed). As a result, even if a situation occurs in which the air bubbles BB are likely to gather around the upper portion of the processing tank 110, the etching liquid LQ is reliably easily supplied to the upper portion of the substrate W. Therefore, the etching liquid LQ easily etches the upper portion of the substrate W. That is, the etching rate in the upper portion of the substrate W increases. As a result, the etching uniformity in the surface of the substrate W is improved. In this manner, the substrate processing method according to the first embodiment can reduce processing unevenness in the surface of the substrate W.

### 2. Second Embodiment

### 2-1. Control Example of Supply of Etching Liquid and Air Bubbles

In the first embodiment described above, the controller 161 needs to adjust the discharge amount of the etching liquid LQ so that the discharge amount of the etching liquid LQ discharged from the upper discharge hole 131a is larger than the discharge amount of the etching liquid LQ discharged from the lower discharge hole 132a. However, the control performed by the controller 161 is not limited thereto.

That is, in a second embodiment, the discharge amount of the etching liquid LQ may be adjusted so that the discharge amount of the etching liquid LQ discharged from the upper discharge hole 131a and the discharge amount of the etching liquid LQ discharged from the lower discharge hole 132a become the same. Hereinafter, a description will be given with reference to the drawings.

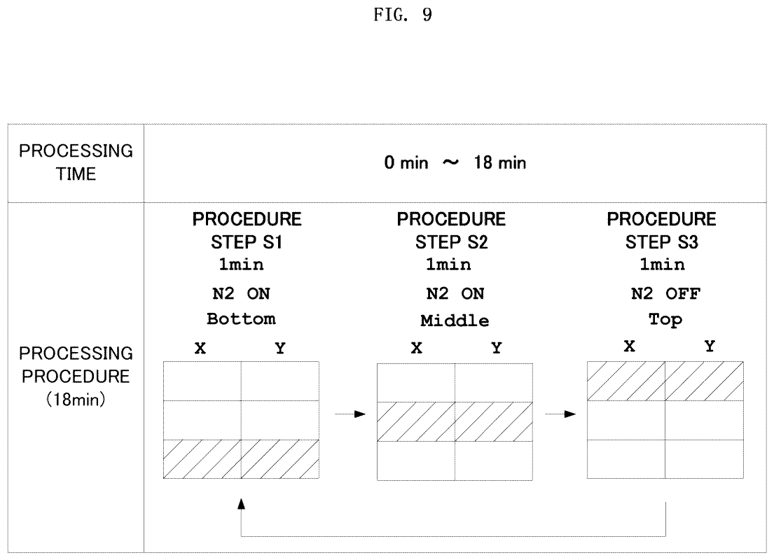

Next, a control example of supply of the etching liquid LQ and the air bubbles BB will be described with reference to FIG. 9.

FIG. 9 is a drawing illustrating an example of a processing procedure of the etching liquid supply unit 130 and the air bubble supply unit 140 according to the second embodiment.

The total processing time is, for example, 18 minutes. Procedure steps S1, S2, and S3 are repeated in this order until the end of the processing time. The procedure of the etching liquid supply processing is not limited to the order of procedure steps S1, S2, and S3.

In procedure step S1, the bottom etching liquid supply units 133X and 133Y supply the etching liquid LQ to the substrate W. The processing time of procedure step S1 is, for example, 1 minute. In procedure step S1, the air bubble supply unit 140 supplies the air bubbles BB to the substrate W.

In procedure step S2, the lower etching liquid supply units 132X and 132Y supply the etching liquid LQ to the substrate W. The processing time of procedure step S2 is, for example, 1 minute. In procedure step S2, the air bubble supply unit 140 supplies the air bubbles BB to the substrate W.

In procedure step S3, the upper etching liquid supply units 131X and 131Y supply the etching liquid LQ to the substrate W. The processing time of procedure step S3 is, for example, 1 minute. In procedure step S3, the air bubble supply unit 140 does not supply the air bubbles BB to the substrate W. That is, in procedure step S3, the upper etching liquid supply units 131X and 131Y supply the etching liquid LQ to the substrate W with no air bubbles BB being supplied to the substrate W for a total of 1 minute.

Thereafter, procedure steps S1, S2, and S3 are repeated in this order until the end of the processing time. Specifically, the bottom etching liquid supply units 133X and 133Y supply the etching liquid LQ to the substrate W with the air bubbles BB being supplied to the substrate W for a total of 6 minutes.

The lower etching liquid supply units 132X and 132Y supply the etching liquid LQ to the substrate W with the air bubbles BB being supplied to the substrate W for a total of 6 minutes.

The upper etching liquid supply units 131X and 131Y supply the etching liquid LQ to the substrate W with no air bubbles BB being supplied to the substrate W for a total of 6 minutes.

### 2-2. State in Processing Tank in which Supply of Etching Liquid and Air Bubbles is Controlled

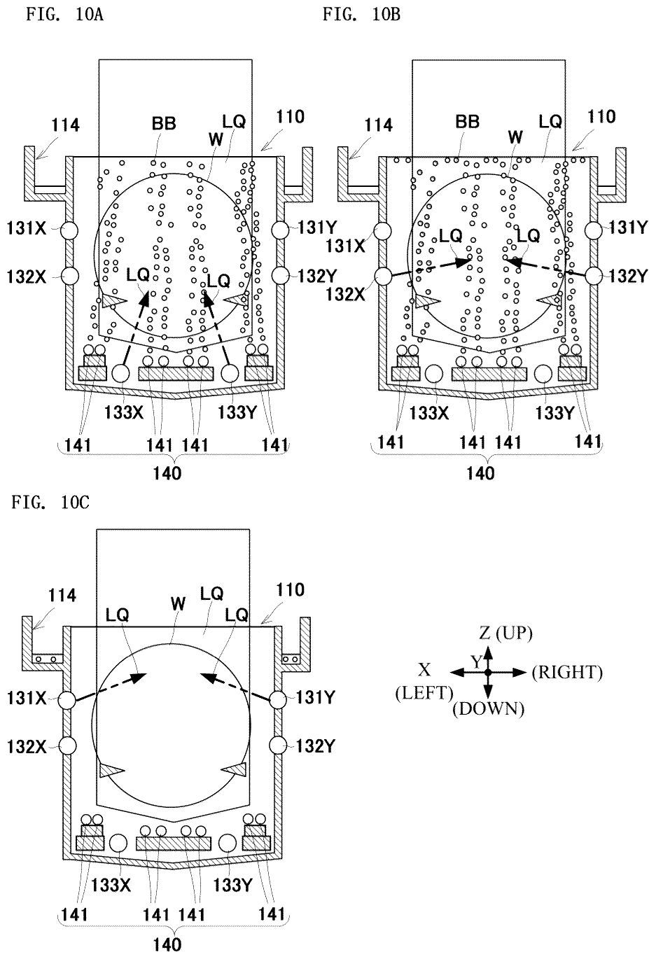

With reference to FIGS. 10A to 10C, a state in the processing tank 110 in which the supply of the etching liquid LQ and the air bubbles BB is controlled by the etching liquid supply unit 130 and the air bubble supply unit 140 according to the above-described processing procedure will be described.

FIGS. 10A to 10C are drawings illustrating the states in the processing tank 110 in which the supply of the etching liquid LQ and the air bubbles BB is controlled according to procedure steps S1 to S3 of the second embodiment.

As illustrated in FIG. 10A, in procedure step S1, the air bubble supply unit 140 supplies the air bubbles BB from the bottom portion of the processing tank 110. The bottom etching liquid supply units 133X and 133Y supply the etching liquid LQ.

As illustrated in FIG. 10B, in procedure step S2, the air bubble supply unit 140 supplies the air bubbles BB from the bottom portion of the processing tank 110. The lower etching liquid supply units 132X and 132Y supply the etching liquid LQ.

As illustrated in FIG. 10C, in procedure step S3, the supply of the air bubbles BB is stopped. The upper etching liquid supply units 131X and 131Y supply the etching liquid LQ.

In procedure steps S1 and S2, the etching liquid LQ is supplied in a state where the air bubbles BB gather in the processing tank 110. However, in procedure step S3, the etching liquid LQ is supplied to the upper portion of the substrate W in a state where the air bubbles BB are not supplied.

As described above, during a period in which the etching liquid LQ is supplied from the upper etching liquid supply units 131X and 131Y, the etching liquid LQ can be supplied to the upper portion of the substrate W in a state where the flow of the etching liquid LQ is hardly diffused by the air bubbles BB. As a result, the etching liquid LQ can be intensively supplied to the upper portion of the substrate W. As a result, the etching rate in the upper portion of the substrate W can be improved.

### 2-3. Substrate Processing Method According to Second Embodiment

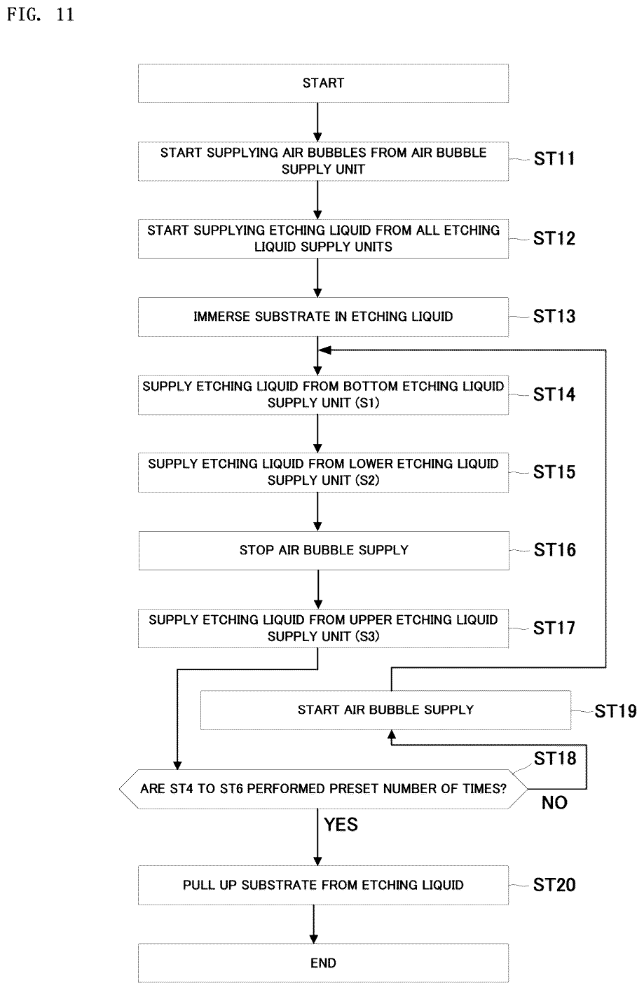

Next, a substrate processing method according to the second embodiment will be described with reference to FIG. 11. The substrate processing method is executed by the substrate processing apparatus 100. FIG. 11 is a flowchart illustrating the substrate processing method according to the second embodiment.

As illustrated in FIG. 11, the substrate processing method includes steps ST11 to ST20. Steps ST11 to ST20 are executed under the control of the controller 161.

### (Step ST11: Air Bubble Supply Step)

In step ST11, each air bubble supply pipe 142 of the air bubble supply unit 140 starts supplying the plurality of air bubbles BB to the etching liquid LQ stored in the processing tank 110 in a similar manner to step ST1 of the first embodiment. Step ST11 corresponds to an example of the “air bubble supply step” of the present invention.

### (Step ST12: Etching Liquid Supply Step)

In step ST12, all the units of the etching liquid supply unit 130 start supplying the etching liquid LQ toward the etching liquid LQ stored in the processing tank 110 in a similar manner to step ST2 of the first embodiment. The etching liquid LQ is supplied in a state of being heated to a temperature suitable for etching. By supplying the etching liquid LQ from all the units of the etching liquid supply unit 130, the temperature of the etching liquid LQ stored in the processing tank 110 can be made uniform. Step ST12 corresponds to an example of the “air bubble supply step” of the present invention.

### (Step ST13: Immersion Step)

In step ST13, the substrate holder 120 immerses the substrate W in the etching liquid LQ stored in the processing tank 110 in a similar manner to step ST3 of the first embodiment. Step ST13 corresponds to an example of the “immersion step” of the present invention.

Next, in steps ST14 to ST17, the behavior of the air bubbles BB is controlled by supplying the etching liquid LQ from the etching liquid supply unit 130 toward the substrate W while switching the respective units of the etching liquid supply unit 130.

### (Step ST14: Bottom Etching Liquid Supply Step (Etching Liquid Discharge Amount Adjustment Step))

In step ST14, the bottom etching liquid supply units 133X and 133Y supply the etching liquid LQ toward the substrate W. That is, the etching liquid discharge amount adjustment units 135 adjust the discharge amount of the etching liquid LQ so as to continue the supply of the etching liquid LQ from the bottom etching liquid supply units 133X and 133Y toward the substrate W. The etching liquid discharge amount adjustment units 135 also adjust the discharge amount of the etching liquid LQ so as to stop the supply of the etching liquid LQ from the upper etching liquid supply units 131X and 131Y and the lower etching liquid supply units 132X and 132Y toward the substrate W.

Step ST14 corresponds to procedure step S1 described above. Step ST14 corresponds to an example of the “etching liquid supply step” of the present invention. Step ST14 also corresponds to an example of the etching liquid discharge amount adjustment step.

### (Step ST15: Lower Etching Liquid Supply Step (Etching Liquid Discharge Amount Adjustment Step))

In step ST15, the lower etching liquid supply units 132X and 132Y supply the etching liquid LQ toward the substrate W. That is, the etching liquid discharge amount adjustment units 135 adjust the discharge amount of the etching liquid LQ so as to start the supply of the etching liquid LQ from the lower etching liquid supply units 132X and 132Y toward the substrate W. The etching liquid discharge amount adjustment units 135 also adjust the discharge amount of the etching liquid LQ so as to continue the supply stop of the etching liquid LQ from the upper etching liquid supply units 131X and 131Y toward the substrate W. The etching liquid discharge amount adjustment units 135 also adjust the discharge amount of the etching liquid LQ so as to stop the supply of the etching liquid LQ from the bottom etching liquid supply units 133X and 133Y toward the substrate W.

Step ST15 corresponds to procedure step S2 described above. Step ST15 corresponds to an example of the “etching liquid supply step” of the present invention. Step ST15 also corresponds to an example of the etching liquid discharge amount adjustment step.

### (Step ST16: Air Bubble Supply Step (Air Bubble Adjustment Step))

In step ST16, the supply of the air bubbles BB from the air bubble supply unit 140 toward the lower side of the substrate W is stopped. That is, the air bubble discharge amount adjustment unit 145 adjusts the discharge amount of the air bubbles BB so as to stop the supply of the air bubbles BB from the air bubble supply unit 140 toward the lower side of the substrate W.

Step ST16 is included in procedure step S3 described above. Step ST16 corresponds to an example of the “air bubble supply step” of the present invention. Step ST16 also corresponds to an example of the air bubble discharge amount adjustment step.

### (Step ST17: Upper Etching Liquid Supply Step (Etching Liquid Discharge Amount Adjustment Step))

In step ST17, the upper etching liquid supply units 131X and 131Y supply the etching liquid LQ toward the substrate W. That is, the etching liquid discharge amount adjustment units 135 adjust the discharge amount of the etching liquid LQ so as to start the supply of the etching liquid LQ from the upper etching liquid supply units 131X and 131Y toward the substrate W. The etching liquid discharge amount adjustment units 135 also adjust the discharge amount of the etching liquid LQ so as to continue the supply stop of the etching liquid LQ from the bottom etching liquid supply units 133X and 133Y toward the substrate W. The etching liquid discharge amount adjustment units 135 also adjust the discharge amount of the etching liquid LQ so as to stop the supply of the etching liquid LQ from the lower etching liquid supply units 132X and 132Y toward the substrate W.

Step ST17 corresponds to procedure step S3 described above. Step ST17 corresponds to an example of the “etching liquid supply step” of the present invention. Step ST17 also corresponds to an example of the etching liquid discharge amount adjustment step.

### (Step ST18: Etching Liquid Supply Step (Etching Liquid Discharge Amount Adjustment Step) (Supply Number of Times Determination Step))

In step ST18, the controller 161 determines whether the processing of steps ST14 to ST17 described above has been performed a preset number of times. The preset number of times is stored in the memory 162 of the control device 160, for example. The preset number of times may be input by an operator via an input unit provided in the substrate processing apparatus 100.

In a case where the preset number of times has not been reached, the supply of the etching liquid LQ from the upper etching liquid supply units 131X and 131Y toward the substrate W is stopped. Then, the process proceeds to step ST19. That is, in step ST18, the etching liquid discharge amount adjustment units 135 adjust the discharge amount of the etching liquid LQ so as to stop the supply of the etching liquid LQ from the upper etching liquid supply units 131X and 131Y toward the substrate W. The etching liquid discharge amount adjustment units 135 also adjust the discharge amount of the etching liquid LQ so as to continue the supply stop of the etching liquid LQ from the lower etching liquid supply units 132X and 132Y toward the substrate W. Step ST14 is executed immediately after the execution of step ST19. Therefore, the etching liquid discharge amount adjustment units 135 adjust the discharge amount of the etching liquid LQ so as to start the supply of the etching liquid LQ from the bottom etching liquid supply units 133X and 133Y toward the substrate W.

In a case where the preset number of times has been reached, the supply of the etching liquid LQ from the upper etching liquid supply units 131X and 131Y toward the substrate W is stopped. Then, the process proceeds to step ST20. That is, in step ST18, the etching liquid discharge amount adjustment units 135 adjust the discharge amount of the etching liquid LQ so as to stop the supply of the etching liquid LQ from the upper etching liquid supply units 131X and 131Y toward the substrate W. The etching liquid discharge amount adjustment units 135 also adjust the discharge amount of the etching liquid LQ so as to continue the supply stop of the etching liquid LQ from the lower etching liquid supply units 132X and 132Y and the bottom etching liquid supply units 133X and 133Y toward the substrate W.

Step ST18 corresponds to an example of the “etching liquid supply step” of the present invention. Step ST18 also corresponds to an example of the etching liquid discharge amount adjustment step.

### (Step ST19: Air Bubble Supply Step (Air Bubble Adjustment Step))

In step ST19, the supply of the air bubbles BB from the air bubble supply unit 140 toward the lower side of the substrate W is restarted. That is, the air bubble discharge amount adjustment unit 145 adjusts the discharge amount of the air bubbles BB so as to restart the supply of the air bubbles BB from the air bubble supply unit 140 toward the lower side of the substrate W.

Step ST19 is included in procedure step S1 described above. Step ST19 corresponds to an example of the “air bubble supply step” of the present invention. Step ST19 also corresponds to an example of the air bubble adjustment step.

In step ST20, the substrate holder 120 pulls up the substrate W from the etching liquid LQ. As a result, the substrate processing method ends.

### 2-4. Effects of Second Embodiment

As described above, according to the substrate processing apparatus 100 of the second embodiment, the controller 161 controls the etching liquid supply unit 130 to switch between the discharge of the etching liquid LQ from the upper discharge hole 131a and the discharge of the etching liquid LQ from the lower discharge hole 132a and the bottom discharge hole 133a. At the same time, the controller 161 controls the air bubble supply unit 140 to adjust the discharge amount of the plurality of air bubbles BB so that the discharge amount of the plurality of air bubbles BB during a period in which the etching liquid LQ is discharged from the upper discharge hole 131a is smaller than the discharge amount of the plurality of air bubbles BB during a period in which the etching liquid LQ is discharged from the lower discharge hole 132a. The controller 161 also controls the air bubble supply unit 140 to adjust the discharge amount of the plurality of air bubbles BB so that the discharge amount of the plurality of air bubbles BB during the period in which the etching liquid LQ is discharged from the upper discharge hole 131a is smaller than the discharge amount of the plurality of air bubbles BB during a period in which the etching liquid LQ is discharged from the bottom discharge hole 133a. As a result, during the period in which the etching liquid is discharged from the upper discharge hole 131a, the etching liquid LQ directed toward the upper portion of the substrate W is less likely to be dispersed by the air bubbles BB. That is, the etching liquid LQ is intensively supplied to the upper portion of the substrate W. Therefore, the etching rate in the upper portion of the substrate W can be increased. As a result, the etching uniformity in the surface of the substrate W is improved. In this manner, the present invention can reduce processing unevenness in the surface of the substrate W.

In the substrate processing apparatus 100 according to the second embodiment, the controller 161 controls the air bubble supply unit 140 to stop the discharge of the plurality of air bubbles BB during the period in which the etching liquid LQ is discharged from the upper discharge hole 131a. As a result, during a period in which the discharge of the plurality of air bubbles BB is stopped, the etching liquid LQ directed toward the upper portion of the substrate W is further less likely to be dispersed by the air bubbles BB. That is, the etching liquid LQ is more easily intensively supplied to the upper portion of the substrate W. Therefore, the etching rate in the upper portion of the substrate W can be further increased. As a result, the etching uniformity in the surface of the substrate W can be further improved.

In the substrate processing method according to the second embodiment, the substrate processing method is a method of processing the substrate. The substrate processing method includes the immersion step (for example, step ST13), the etching liquid supply step (for example, steps ST12, ST14, ST15, ST17, and ST18), and the air bubble supply step (for example, steps ST11, ST16, and ST19). In the immersion step, the substrate W held by the substrate holder 120 is immersed in the etching liquid stored in the processing tank 110 in step ST3. In the etching liquid supply step, the etching liquid LQ is supplied into the processing tank 110 in which the substrate W is immersed in steps ST14, ST15, and ST17. In the air bubble supply step, the plurality of air bubbles BB are supplied into the processing tank 110 in which the substrate W is immersed in steps ST11 and ST19 during the execution of steps ST14 and ST15. The etching liquid supply step switches between the step of discharging the etching liquid LQ toward the upper portion of the substrate W (for example, step ST17) and the step of discharging the etching liquid toward the lower portion of the substrate (for example, steps ST14 and ST15) during a period in which the substrate W is etched. Along with this switching, in the air bubble supply step (for example, step ST16), the discharge amount of the plurality of air bubbles BB is adjusted so that the discharge amount of the plurality of air bubbles during a period in which the etching liquid is discharged toward the upper portion of the substrate W (for example, a period in which step ST17 is executed) is smaller than the discharge amount of the plurality of air bubbles BB during a period in which the etching liquid is discharged toward the lower portion of the substrate (for example, a period in which steps ST14 and ST15 are executed). As a result, during the period in which the etching liquid is discharged toward the upper portion of the substrate (for example, the period in which step ST17 is executed), the etching liquid LQ directed toward the upper portion of the substrate W is less likely to be dispersed by the air bubbles. That is, the etching liquid LQ is intensively supplied to the upper portion of the substrate W. Therefore, the etching rate in the upper portion of the substrate W can be increased. As a result, the etching uniformity in the surface of the substrate W is improved. In this manner, the substrate processing method according to the second embodiment can reduce processing unevenness in the surface of the substrate W.

The present invention is not limited to the embodiments, and can be modified as follows.
(1) In the first embodiment and the second embodiment described above, the processing tank 110 includes the upper etching liquid supply unit 131, the lower etching liquid supply unit 132, and the bottom etching liquid supply unit 133. However, the configuration of the processing tank 110 is not limited thereto. That is, the processing tank 110 may include only the upper etching liquid supply unit 131 and the lower etching liquid supply unit 132. The processing tank 110 may include only the upper etching liquid supply unit 131 and the bottom etching liquid supply unit 133.
(2) In the first embodiment and the second embodiment described above, the upper etching liquid supply unit 131 is one etching liquid supply pipe. The lower etching liquid supply unit 132 is one etching liquid supply pipe. However, the configuration of the upper etching liquid supply unit 131 and the lower etching liquid supply unit 132 is not limited thereto. That is, the upper etching liquid supply unit 131 may be a plurality of etching liquid supply pipes. The lower etching liquid supply unit 132 may be a plurality of etching liquid supply pipes.

In the first embodiment and the second embodiment described above, the bottom etching liquid supply unit 133 is a plurality of etching liquid supply pipes. However, the bottom etching liquid supply unit 133 may be one etching liquid supply pipe.
(3) In the first embodiment and the second embodiment described above, the processing procedure of the etching liquid supply unit 130 and the air bubble supply unit 140 is in the order of procedure steps S1, S2, and S3, but may be in a different order.

In the first embodiment described above, procedure steps S1, S2, and S3 are performed a predetermined number of times, and then procedure step S4 is performed. However, procedure step S4 may be performed while procedure steps S1, S2, and S3 are performed a predetermined number of times. Procedure step S4 may be performed more than once.

In the first embodiment and the second embodiment described above, for example, in procedure step S1, the etching liquid LQ is supplied from both the bottom etching liquid supply units 133X and 133Y. However, in procedure step S1, the etching liquid LQ may be supplied from either of the bottom etching liquid supply units 133X and 133Y. In procedure step S1, the etching liquid LQ may be supplied from the lower etching liquid supply units 132X and 132Y and/or the bottom etching liquid supply units 133X and 133Y. The same applies to procedure steps S2 and S3.
(4) In the flowcharts illustrated in FIGS. 8 and 11 in the first embodiment and the second embodiment described above, the supply start of the air bubbles BB (step ST1), the supply start of the etching liquid LQ (step ST2), and the immersion of the substrate W in the etching liquid LQ (step ST3) are performed in this order, but this order may be changed. These steps may also be performed at the same time.
(5) In the first embodiment described above, the discharge of the etching liquid LQ is adjusted so that the discharge amount (for example, discharge amount=20) of the etching liquid LQ discharged from the upper discharge hole 131a is larger than the discharge amount (discharge amount=0) of the etching liquid LQ discharged from each of the lower discharge hole 132a and the bottom discharge hole 133a in a part of the period in which the substrate W is etched (for example, a period in which procedure step S4 is performed). This can also be rephrased as follows. That is, the discharge of the etching liquid LQ is adjusted so that the total discharge amount (for example, total discharge amount=80) of the etching liquid LQ discharged from the upper discharge hole 131a is larger than the total discharge amount (for example, total discharge amount=60) of the etching liquid LQ discharged from each of the lower discharge hole 132a and the bottom discharge hole 133a in the whole period in which the substrate W is etched.

The discharge amount of the etching liquid LQ described above is a value when the discharge amount of the etching liquid LQ per minute discharged from each of the upper discharge hole 131a, the lower discharge hole 132a, and the bottom discharge hole 133a is 10.
(6) In the first embodiment described above, the controller 161 controls the etching liquid supply unit 130 to make different the supply amount of the etching liquid LQ and the supply time of the etching liquid LQ. However, the embodiment of the present invention is not limited thereto. That is, in the substrate processing apparatus 100, the controller 161 may control the etching liquid supply unit 130 to adjust the discharge amount of the etching liquid LQ so that the amount per unit time of the etching liquid LQ discharged from the upper discharge hole 131a is larger than the amount per unit time of the etching liquid LQ discharged from the lower discharge hole 132a. Therefore, it is easy to make the discharge amount of the etching liquid LQ discharged from the upper discharge hole 131a larger than the discharge amount of the etching liquid discharged from the lower discharge hole 132a.
(7) In the first embodiment described above, the discharge of the etching liquid LQ is adjusted so that the discharge amount (for example, discharge amount=20) of the etching liquid LQ discharged from the upper discharge hole 131a is larger than the discharge amount (discharge amount=0) of the etching liquid LQ discharged from each of the lower discharge hole 132a and the bottom discharge hole 133a in a part of the period in which the substrate W is etched (for example, the period in which procedure step S4 is executed). However, the embodiment of the present invention is not limited thereto. That is, the discharge of the etching liquid LQ may be adjusted so that the discharge amount of the etching liquid LQ discharged from the upper discharge hole 131a is larger than the discharge amount of the etching liquid LQ discharged from the lower discharge hole 132a in the whole period in which the substrate W is etched. Specifically, for example, the discharge amount per unit time of the etching liquid LQ discharged from the upper discharge hole 131a is larger than the discharge amount per unit time of the etching liquid LQ discharged from the lower discharge hole 132a. Therefore, in any segment of the period in which the substrate W is etched, the discharge amount of the etching liquid LQ discharged from the upper discharge hole 131a is larger than the discharge amount of the etching liquid LQ discharged from the lower discharge hole 132a.
(8) In the first embodiment described above, the discharge amount of the etching liquid LQ discharged from each of the upper discharge hole 131a, the lower discharge hole 132a, and the bottom discharge hole 133a is the same during a period in which procedure steps S1 to S3 are repeated, and the discharge amount of the etching liquid LQ discharged from the upper discharge hole 131a exceeds the discharge amount of the etching liquid LQ discharged from each of the lower discharge hole 132a and the bottom discharge hole 133a in procedure step S4 performed last. However, the embodiment of the present invention is not limited thereto. The discharge amount of the etching liquid LQ discharged from the upper discharge hole 131a may exceed the discharge amount of the etching liquid LQ discharged from each of the lower discharge hole 132a and the bottom discharge hole 133a during the period in which procedure steps S1 to S3 are repeated. In this case, procedure step S4 does not have to be executed.

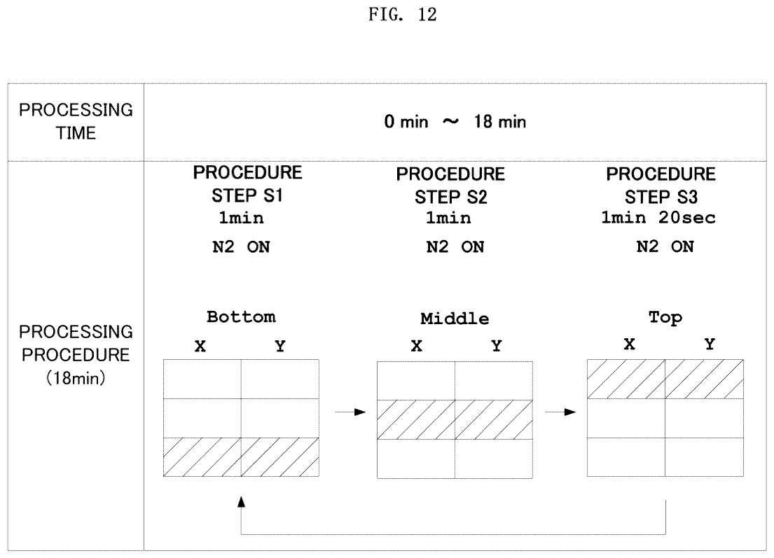

Reference is made to FIG. 12. FIG. 12 is a drawing illustrating an example of a processing procedure of an etching liquid supply unit and an air bubble supply unit according to an eighth modification.

In procedure steps S1 to S3, the etching liquid LQ is supplied from each of the bottom etching liquid supply units 133X and 133Y, the lower etching liquid supply units 132X and 132Y, and the upper etching liquid supply units 131X and 131Y in a state where the air bubbles BB are supplied in a similar manner to procedure steps S1 to S3 of the first embodiment described above. The processing time of each of procedure steps S1 and S2 is 1 minute.

The processing time of procedure step S3 is 1 minute and 20 seconds. Suppose that the discharge amount per minute from each of the bottom discharge hole 133a, the lower discharge hole 132a, and the upper discharge hole 131a is 10. At this time, the total discharge amount from each of the bottom discharge hole 133a and the lower discharge hole 132a is 60. The total discharge amount from the upper discharge hole 131a is 80.

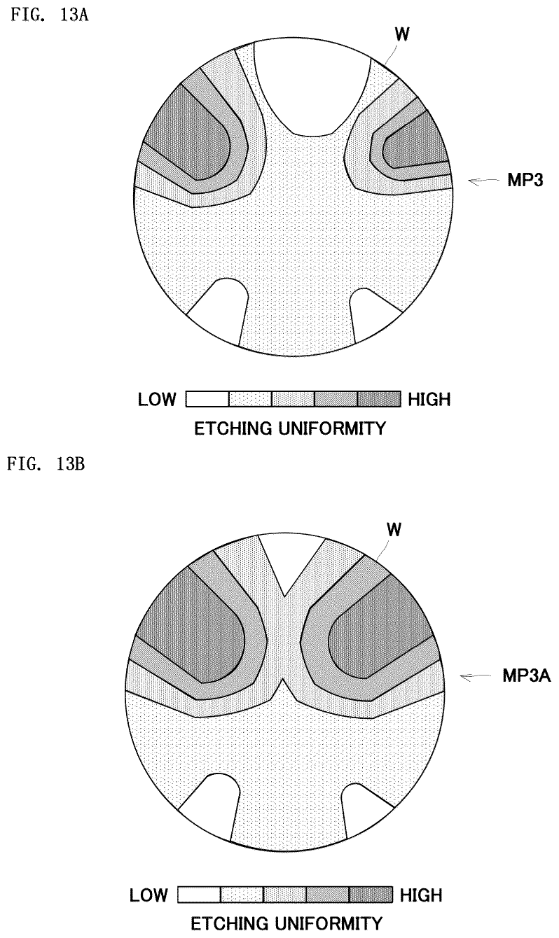

Reference is made to FIG. 13A. FIG. 13A is the map image MP3 illustrating the uniformity of etching in the surface of the substrate W in a case where the supply of the etching liquid LQ and the air bubbles BB is controlled according to procedure step S3 of the first embodiment.

The map image MP3 illustrates the uniformity of etching in a case where the etching liquid LQ is discharged from the upper discharge hole 131a in a state where the air bubbles BB are supplied for 6 minutes. In the map image MP3, the etching uniformity on the opposite outer sides of the upper portion of the substrate W is the highest. Then, the etching uniformity in most of the peripheral portion of the opposite outer sides of the upper portion of the substrate W is also relatively high. However, no region extends to the center of the substrate W. Therefore, a region having the lowest etching uniformity remains in the center of the upper portion of the substrate.

Reference is made to FIG. 13B. FIG. 13B is a map image MP3A illustrating the uniformity of etching in the surface of the substrate W in a case where the supply of the etching liquid LQ and the air bubbles BB is controlled according to procedure step S3 of the eighth modification.

The map image MP3A illustrates the uniformity of etching in a case where the etching liquid LQ is discharged from the upper discharge hole 131a in a state where the air bubbles BB are supplied for 8 minutes. In the map image MP3A, a region having the highest etching uniformity on the opposite outer sides of the upper portion of the substrate W extends to a region near the center of the substrate W. A region having relatively high etching uniformity in the peripheral portion of the opposite outer sides of the upper portion of the substrate W extends to the center of the substrate W. As a result, a region having the lowest etching uniformity at the center of the upper portion of the substrate W is smaller.

As described above, the etching rate at the center of the upper portion of the substrate W can be improved by making the discharge amount of the etching liquid LQ discharged from the upper discharge hole 131a in a state where the air bubbles BB are supplied larger than the discharge amount of the etching liquid LQ discharged from each of the lower discharge hole 132a and the bottom discharge hole 133a in a state where the air bubbles BB are supplied.
(9) In the first embodiment and the second embodiment described above, the period in which the etching liquid LQ is discharged from the bottom discharge hole 133a is set in procedure step S1, the period in which the etching liquid LQ is discharged from the lower discharge hole 132a is set in procedure step S2, and the period in which the etching liquid LQ is discharged from the upper discharge hole 131a is set in procedure step S3. However, the embodiments of the present invention are not limited thereto.

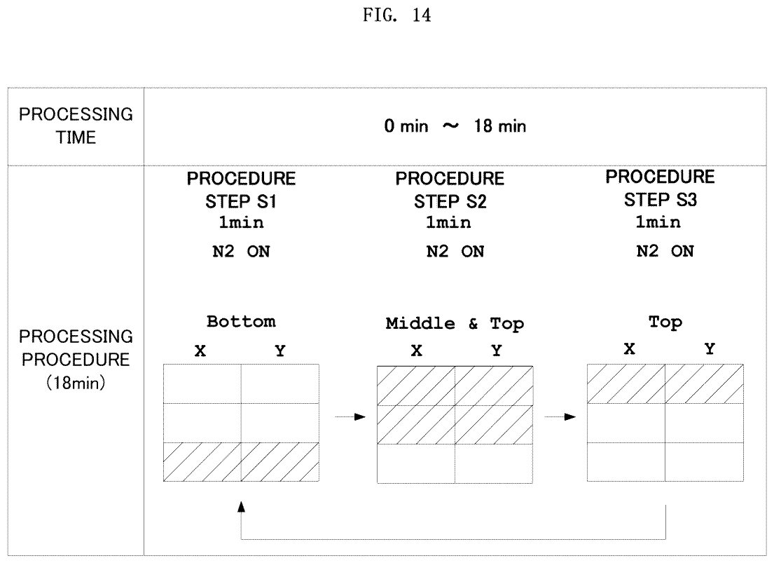

Reference is made to FIG. 14. FIG. 14 is a drawing illustrating an example of a processing procedure of an etching liquid supply unit and an air bubble supply unit according to a ninth modification.

The processing time of each of procedure steps S1 to S3 is 1 minute. The total processing time is 18 minutes. In procedure step S1, the etching liquid LQ is supplied from the bottom discharge hole 133a in a state where the air bubbles BB are supplied in a similar manner to the first embodiment and the second embodiment. The discharge amount of the etching liquid LQ from the bottom discharge hole 133a in procedure step S1 is 60.

Procedure steps S2 and S3 are different from those of the first embodiment and the second embodiment. That is, in procedure step S2, the etching liquid LQ is supplied from the upper discharge hole 131a and the lower discharge hole 132a in a state where the air bubbles BB are supplied. In procedure step S3, the etching liquid LQ is supplied from the upper discharge hole 131a in a state where the air bubbles BB are supplied. The discharge amount of the etching liquid LQ from the lower discharge hole 132a in procedure step S2 is 60. The discharge amount of the etching liquid LQ from the upper discharge hole 131a in procedure steps S2 and S3 is 120.

As described above, the period in which the etching liquid LQ is supplied from the upper discharge hole 131a is not limited to procedure step S3. The period in which the etching liquid LQ is supplied from the upper discharge hole 131a may be set in procedure step S1 or S2.
(10) In the first embodiment described above, the discharge of the etching liquid LQ is adjusted so that the discharge amount of the etching liquid LQ discharged from the upper discharge hole 131a is larger than the discharge amount (discharge amount=0) of the etching liquid LQ discharged from the bottom discharge hole 133a in a part of the period in which the substrate W is etched (for example, the remaining 2 minutes). However, the embodiment of the present invention is not limited thereto. That is, the discharge of the etching liquid LQ may be adjusted so that the discharge amount of the etching liquid LQ discharged from the upper discharge hole 131a is larger than the discharge amount of the etching liquid LQ discharged from the bottom discharge hole 133a in the whole period in which the substrate W is etched. Specifically, for example, the discharge amount per unit time of the etching liquid LQ discharged from the upper discharge hole 131a is larger than the discharge amount per unit time of the etching liquid LQ discharged from the bottom discharge hole 133a. Therefore, in any segment of the period in which the substrate W is etched, the discharge amount of the etching liquid LQ discharged from the upper discharge hole 131a is larger than the discharge amount of the etching liquid LQ discharged from the bottom discharge hole 133a.
(11) In the second embodiment described above, the controller 161 controls the air bubble supply unit 140 to stop the discharge of the plurality of air bubbles BB during the period in which the etching liquid LQ is discharged from the upper discharge hole 131a. However, the embodiment of the present invention is not limited thereto. That is, in the substrate processing apparatus 100, the controller 161 may control the air bubble supply unit 140 to switch between the discharge of the plurality of air bubbles BB and the discharge stop of the plurality of air bubbles BB during the period in which the etching liquid LQ is discharged from the upper discharge hole 131a. It is possible to achieve both the diffusion action of the flow of the etching liquid LQ due to the supply of the plurality of air bubbles BB to the substrate W and the action of concentrating the flow of the etching liquid LQ in the upper portion of the substrate W due to the non-supply of the plurality of air bubbles BB to the substrate W. As a result, the etching rate in the upper portion of the substrate W can be effectively increased.

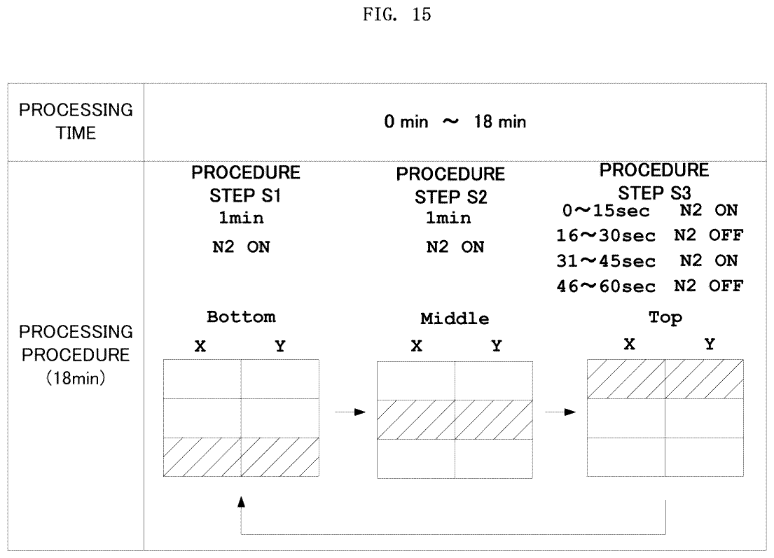

Specifically, reference is made to FIG. 15. FIG. 15 is a drawing illustrating an example of a processing procedure of an etching liquid supply unit and an air bubble supply unit according to an eleventh modification.

Similarly to the first embodiment and the second embodiment described above, the processing time of each of procedure steps S1 to S3 is 1 minute. Similarly to the first embodiment and the second embodiment described above, in procedure steps S1 and S2, the supply of the etching liquid LQ is switched in the order of the bottom etching liquid supply units 133X and 133Y and the lower etching liquid supply units 132X and 132Y while the air bubbles BB are being supplied.

Procedure step S3 is different from those of the first embodiment and the second embodiment described above. That is, in procedure step S3, the supply and supply stop of the air bubbles BB are switched, for example, every 15 seconds during the period in which the etching liquid LQ is supplied from the upper etching liquid supply units 131X and 131Y. Specifically, the air bubbles BB are supplied from 0 to 15 seconds. The supply of the air bubbles BB is stopped from 16 to 30 seconds. The air bubbles BB are supplied from 31 to 45 seconds. The supply of the air bubbles BB is stopped from 46 to 60 seconds.

This modification is not limited to the configuration in which the supply and supply stop of the air bubbles BB are switched every 15 seconds. The air bubbles BB may be supplied for 45 seconds, and the supply of the air bubbles BB may be stopped for 15 seconds. The air bubbles BB may be supplied for 15 seconds, and the supply of the air bubbles BB may be stopped for 45 seconds. The etching of the upper portion of the substrate W can be controlled by changing the time for stopping the supply of the air bubbles BB.

As described above, it is possible to achieve both the diffusion action of the flow of the etching liquid LQ due to the supply of the plurality of air bubbles BB to the substrate W and the action of concentrating the flow of the etching liquid LQ in the upper portion of the substrate W due to the non-supply of the plurality of air bubbles BB to the substrate W during the period in which the etching liquid LQ is supplied from the upper etching liquid supply units 131X and 131Y. As a result, the etching rate in the upper portion of the substrate W can be effectively increased.
(12) In the second embodiment described above, the controller 161 stops the supply of the air bubbles BB every time procedure step S3 is performed during the period in which procedure steps S1, S2, and S3 are repeated. However, the control to stop the supply of the air bubbles BB during the period in which the etching liquid LQ is supplied from the upper etching liquid supply units 131X and 131Y is not limited thereto. That is, the controller 161 may perform control to stop the supply of the air bubbles BB only during an optional period in which procedure step S3 is performed in the period in which the etching liquid LQ is supplied from the upper etching liquid supply units 131X and 131Y.

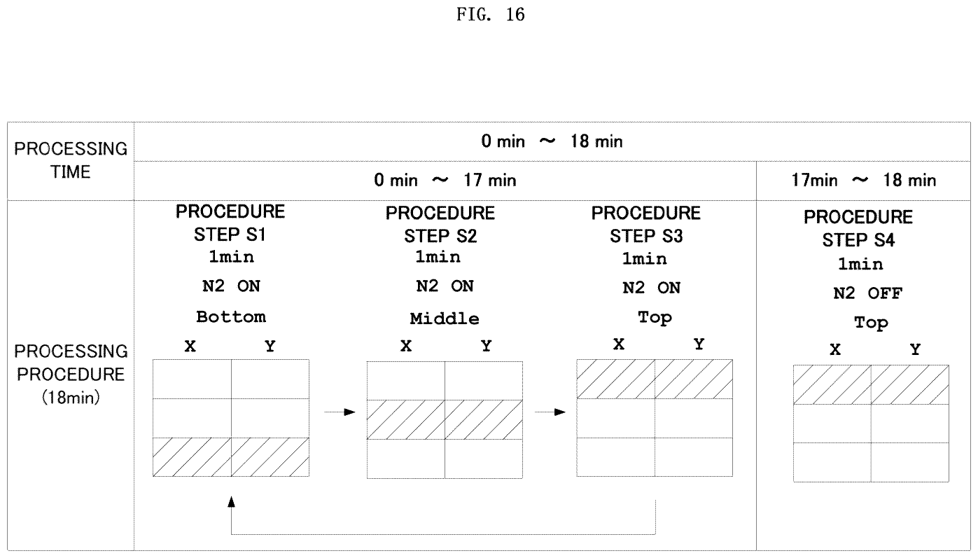

Reference is made to FIG. 16. FIG. 16 is a drawing illustrating an example of a processing procedure of an etching liquid supply unit and an air bubble supply unit according to a twelfth modification.

The processing time of each of procedure steps S1 to S3 is 1 minute. In procedure steps S1 to S3, the supply of the etching liquid LQ is switched in the order of the bottom etching liquid supply units 133X and 133Y, the lower etching liquid supply units 132X and 132Y, and the upper etching liquid supply units 131X and 131Y while the air bubbles BB are being supplied. The total processing time is 18 minutes. Procedure steps S1 to S3 are repeated from the start of the processing to 17 minutes. The supply of the air bubbles BB is stopped only for the last 1 minute (18th minute).

The period in which the supply of the air bubbles BB is stopped is not limited to the last 1 minute. For example, the supply of the air bubbles BB may be stopped for a total of 2 minutes of 9th minute and 18th minute. For example, the supply of the air bubbles BB may be stopped for a total of 3 minutes of 12th minute, 15th minute, and 18th minute.

As described above, it is possible to optionally adjust the period in which the flow of the etching liquid LQ is diffused due to the supply of the plurality of air bubbles BB to the substrate W and the period in which the flow of the etching liquid LQ is concentrated in the upper portion of the substrate W due to the non-supply of the plurality of air bubbles BB to the substrate W during the period in which the etching liquid LQ is supplied from the upper etching liquid supply units 131X and 131Y. As a result, the etching rate in the upper portion of the substrate W can be effectively increased.
(13) In FIG. 1, the direction of the discharge hole of the etching liquid supply unit 130 is not particularly limited. In the upper etching liquid supply units 131X and 131Y, it is only necessary that the flow of the etching liquid LQ is directed to the upper portion of the substrate W. The lower etching liquid supply units 132X and 132Y only need to be disposed below the upper etching liquid supply units 131X and 131Y. The bottom etching liquid supply units 133X and 133Y only need to be disposed below the lower etching liquid supply units 132X and 132Y. In the lower etching liquid supply units 132X and 132Y and the bottom etching liquid supply units 133X and 133Y, the flow direction of the etching liquid LQ is not particularly limited.
(14) In FIG. 2, the etching liquid flow rate adjustment mechanism 136 does not have to include the flow meter a1 and the adjustment valve a2. The gas flow rate adjustment mechanism 146 does not have to include the adjustment valve b1, the flow meter b2, and the filter b3.
(15) In FIG. 1, the mechanism for supplying the air bubbles BB is not limited to the air bubble supply pipe 142. For example, the air bubbles BB may be supplied from a plurality of holes provided in a punching plate disposed at the bottom portion of the processing tank 110.
(16) In the first embodiment and the second embodiment described above, it has been described that when the valve a3 opens and closes the supply pipe P2 in the etching liquid flow rate adjustment mechanism 136, the valve a3 switches between the supply and supply stop of the etching liquid LQ from the etching liquid supply unit 130 into the processing tank 110. In this regard, the controller 161 may control the etching liquid discharge amount adjustment unit 135 to adjust, in a plurality of stages, a minute discharge amount (also referred to as slow leak flow rate) slightly discharged when the etching liquid is adjusted not to be discharged from at least one of the upper discharge hole 131a, the lower discharge hole 132a, or the bottom discharge hole 133a in the whole or a part of the period in which the substrate W is etched.

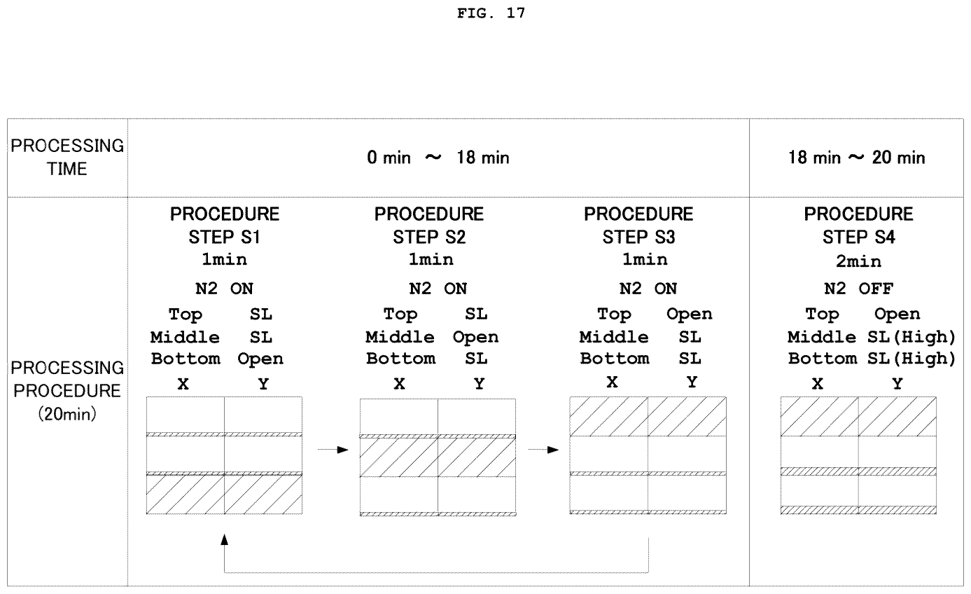

Reference is made to FIG. 17. FIG. 17 is a drawing illustrating an example of a processing procedure of an etching liquid supply unit and an air bubble supply unit according to a sixteenth modification.

Procedure steps S1 to S4 are substantially the same as procedure steps S1 to S4 in the first embodiment. In this modification, when the valve a3 closes the supply pipe P2, the etching liquid LQ is discharged slightly from the upper discharge hole 131a, the lower discharge hole 132a, or the bottom discharge hole 133a. In the drawing, the presence of minute discharge (slow leak) is denoted as “SL”.

In procedure steps S1 to S3, when the valve a3 closes the supply pipe P2, the etching liquid LQ is discharged in a normal minute discharge amount (slow leak flow rate). Specifically, in procedure step S1, when the etching liquid LQ is supplied from the bottom etching liquid supply units 133X and 133Y, the etching liquid LQ is discharged in the normal minute discharge amount (slow leak flow rate) from the upper etching liquid supply units 131X and 131Y and the lower etching liquid supply units 132X and 132Y. In procedure step S2, when the etching liquid LQ is supplied from the lower etching liquid supply units 132X and 132Y, the etching liquid LQ is discharged in the normal minute discharge amount (slow leak flow rate) from the upper etching liquid supply units 131X and 131Y and the bottom etching liquid supply units 133X and 133Y. In procedure step S3, when the etching liquid LQ is supplied from the upper etching liquid supply units 131X and 131Y, the etching liquid LQ is discharged in the normal minute discharge amount (slow leak flow rate) from the lower etching liquid supply units 132X and 132Y and the bottom etching liquid supply units 133X and 133Y.

On the other hand, in procedure step S4, when the etching liquid LQ is supplied from the upper etching liquid supply units 131X and 131Y, the etching liquid LQ is discharged in a larger amount (higher level) than the normal minute discharge amount (slow leak flow rate) from the lower etching liquid supply units 132X and 132Y and the bottom etching liquid supply units 133X and 133Y.

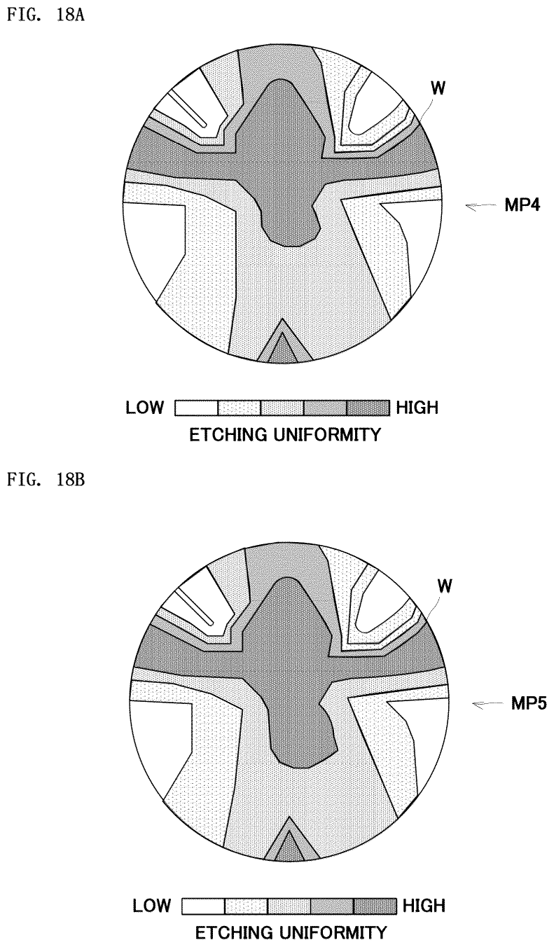

Here, with reference to FIGS. 18A and 18B, the uniformity of etching in a case where the minute discharge amount (slow leak flow rate) changes in procedure steps S3 and S4 will be described. FIGS. 18A and 18B are map images illustrating the uniformity of etching in the surface of the substrate in a case where the supply of the etching liquid and the air bubbles is controlled according to procedure steps S3 and S4 of the sixteenth modification.

FIG. 18A is a map image MP4 when procedure step S3 is performed. The map image MP4 is the same as that described in the first embodiment.

FIG. 18B is a map image MP5 when procedure step S4 is performed. In the map image MP5, a region having the highest etching rate is slightly larger than that in the map image MP4. A peripheral portion of the region having the highest etching rate is also slightly larger than that in the map image MP4.

As described above, the etching rate can be improved by making the etching liquid LQ discharged in the minute discharge amount (slow leak flow rate) from the lower etching liquid supply units 132X and 132Y and the bottom etching liquid supply units 133X and 133Y larger (higher level) than usual during the period in which the etching liquid LQ is supplied from the upper etching liquid supply units 131X and 131Y in procedure step S4.

The timing of adjusting the minute discharge amount (slow leak flow rate) is not limited to procedure step S4, and may be any of procedure steps S1 to S3. By adjusting the minute discharge amount (slow leak flow rate), the etching rate can be locally improved according to the discharge position of the etching liquid in the minute discharge amount (slow leak flow rate).

This makes it possible for the etching liquid discharge amount adjustment unit 135 not only to adjust whether the etching liquid LQ is discharged or not from at least one of the upper discharge hole 131a, the lower discharge hole 132a, or the bottom discharge hole 133a, but also to adjust the minute discharge amount at the time of slightly discharging the etching liquid LQ. Therefore, the etching rate in the surface of the substrate W can be finely adjusted. As a result, the uniformity of etching in the surface of the substrate W can be finely adjusted.
(17) In the first embodiment, the second embodiment, and the modifications described in the above (1) to (16), each configuration may be appropriately changed by being further replaced or combined with a configuration of another modification.

The present invention may be embodied in other specific forms without departing from the spirit or essential attributes thereof and, accordingly, reference should be made to the appended claims, rather than to the foregoing specification, as indicating the scope of the invention.

What is claimed is:

1. A substrate processing apparatus for processing a substrate, comprising:
a processing tank configured to store an etching liquid for etching the substrate;
a substrate holder configured to hold the substrate and immerse the substrate in the etching liquid stored in the processing tank;
an etching liquid supply unit disposed in the processing tank and configured to supply the etching liquid into the processing tank, the etching liquid supply unit including at least a first discharge hole in which a direction in which the etching liquid is discharged is directed to an upper portion of the substrate, and a second discharge hole disposed below the first discharge hole and configured to discharge the etching liquid;
an air bubble supply unit disposed in the processing tank and configured to supply a plurality of air bubbles to the etching liquid from below the substrate; and
a controller configured to control processing on the substrate,
wherein the controller controls the etching liquid supply unit to adjust a discharge amount of the etching liquid so that a discharge amount of the etching liquid discharged from the first discharge hole is larger than a discharge amount of the etching liquid discharged from the second discharge hole in a whole or part of a period in which the substrate is etched.

2. The substrate processing apparatus according to claim 1, wherein
the processing tank includes a bottom portion and a side wall portion that extends upward from the bottom portion,
the side wall portion includes a first side wall portion and a second side wall portion that faces the first side wall portion, and
the first discharge hole and the second discharge hole are provided on each of the first side wall portion side and the second side wall portion side.

3. The substrate processing apparatus according to claim 2, wherein
the etching liquid supply unit includes a third discharge hole disposed in the bottom portion, and discharges the etching liquid from the third discharge hole to a lower side of the substrate, and
the controller controls the etching liquid supply unit to adjust the discharge of the etching liquid so that the discharge amount of the etching liquid discharged from the first discharge hole is larger than at least one of the discharge amount of the etching liquid discharged from the second discharge hole or a discharge amount of the etching liquid discharged from the third discharge hole in the whole or a part of the period in which the substrate is etched.

4. The substrate processing apparatus according to claim 1, wherein the controller controls the etching liquid supply unit to adjust the discharge amount of the etching liquid so that a period in which the etching liquid is discharged from the first discharge hole is longer than a period in which the etching liquid is discharged from the second discharge hole.

5. The substrate processing apparatus according to claim 1, wherein the controller controls the etching liquid supply unit to adjust the discharge amount of the etching liquid so that an amount per unit time of the etching liquid discharged from the first discharge hole is larger than an amount per unit time of the etching liquid discharged from the second discharge hole.

6. A substrate processing apparatus for processing a substrate, comprising:
a processing tank configured to store an etching liquid for etching the substrate;
a substrate holder configured to hold the substrate and immerse the substrate in the etching liquid stored in the processing tank;
an etching liquid supply unit disposed in the processing tank and configured to supply the etching liquid into the processing tank, the etching liquid supply unit including at least a first discharge hole in which a direction in which the etching liquid is discharged is directed to an upper portion of the substrate, and a second discharge hole disposed below the first discharge hole and configured to discharge the etching liquid;
an air bubble supply unit disposed in the processing tank and configured to supply a plurality of air bubbles to the etching liquid from below the substrate; and
a controller configured to control processing on the substrate,
wherein the controller controls the etching liquid supply unit to switch between discharge of the etching liquid from the first discharge hole and discharge of the etching liquid from the second discharge hole, and
controls the air bubble supply unit to adjust a discharge amount of the plurality of air bubbles so that a discharge amount of the plurality of air bubbles during a period in which the etching liquid is discharged from the first discharge hole is smaller than a discharge amount of the plurality of air bubbles during a period in which the etching liquid is discharged from the second discharge hole.

7. The substrate processing apparatus according to claim 6, wherein the controller controls the air bubble supply unit to stop discharge of the plurality of air bubbles during the period in which the etching liquid is discharged from the first discharge hole.

8. The substrate processing apparatus according to claim 6, wherein the controller controls the air bubble supply unit to switch between discharge of the plurality of air bubbles and discharge stop of the plurality of air bubbles during the period in which the etching liquid is discharged from the first discharge hole.

9. A substrate processing method for processing a substrate, comprising:
immersing a substrate held by a substrate holder in an etching liquid stored in a processing tank;
supplying the etching liquid into the processing tank in which the substrate is immersed; and
supplying a plurality of air bubbles into the processing tank in which the substrate is immersed,
wherein the supplying of the etching liquid includes adjusting a discharge amount of the etching liquid so that a discharge amount of the etching liquid discharged toward an upper portion of the substrate is larger than a discharge amount of the etching liquid discharged toward a lower portion of the substrate in a whole or part of a period in which the substrate is etched.

10. A substrate processing method for processing a substrate, comprising:
immersing a substrate held by a substrate holder in an etching liquid stored in a processing tank;
supplying the etching liquid into the processing tank in which the substrate is immersed; and
supplying a plurality of air bubbles into the processing tank in which the substrate is immersed,
wherein the supplying of the etching liquid into the processing tank in which the substrate is immersed includes switching between discharging the etching liquid toward an upper portion of the substrate and discharging the etching liquid toward a lower portion of the substrate during a period in which the substrate is etched, and
the supplying of the plurality of air bubbles into the processing tank in which the substrate is immersed includes adjusting a discharge amount of the plurality of air bubbles so that a discharge amount of the plurality of air bubbles during a period in which the etching liquid is discharged toward the upper portion of the substrate is smaller than a discharge amount of the plurality of air bubbles during a period in which the etching liquid is discharged toward the lower portion of the substrate.
